(19) United States
(12) Patent Application Publication
(10) Pub. No.: US 2025/0329653 A1
(43) Pub. Date: Oct. 23, 2025

(54) SEMICONDUCTOR DEVICE AND MANUFACTURING METHOD OF METAL INTERCONNECTION STRUCTURE

(71) Applicant: Samsung Electronics Co., Ltd., Suwon-si (KR)

(72) Inventors: Seran OH, Suwon-si (KR); Yunho KANG, Suwon-si (KR); Sukhoon KIM, Suwon-si (KR); Yeonuk KIM, Suwon-si (KR); Jangeun LEE, Suwon-si (KR)

(21) Appl. No.: 19/176,249

(22) Filed: Apr. 11, 2025

(30) Foreign Application Priority Data
Apr. 18, 2024 (KR) 10-2024-0052267

(51) Int. Cl. H01L 23/532; H01L 21/768; H01L 23/522; H10D 84/83

(52) U.S. Cl. CPC H01L 23/53261; H01L 21/7682; H01L 21/7685; H01L 23/5226; H01L 23/53247; H01L 23/5329; H10D 84/832; H10D 84/834

(57) ABSTRACT

Provided is a semiconductor device including an activation pattern extended in a first direction, a gate electrode having portions of the gate electrode spaced apart in the first direction on the activation pattern, and extending in a second direction intersecting the first direction, a gate contact on the gate electrode, a source/drain pattern on the activation pattern, a source/drain contact on the source/drain pattern, an insulation layer over the gate contact and the source/drain contact, a via penetrating the insulation layer, wherein the via is on at least one of the gate contact or the source/drain contact, an adhesion layer on the insulation layer, wherein the adhesion layer exposes an upper surface of the via, and an interconnection layer on the first adhesion layer, wherein the upper surface of the via is in contact with a first portion of the interconnection layer, and wherein the first adhesion layer includes tantalum boride (TaB) or an alloy of TaB.

### CROSS-REFERENCE TO RELATED APPLICATION

This U.S. non-provisional application claims the benefit of Korean Patent Application No. 10-2024-0052267, filed on Apr. 18, 2024, in the Korean Intellectual Property Office, the disclosure of which is incorporated herein by reference in its entirety.

### BACKGROUND

### 1. Field of the Disclosure

Example embodiments relate to a semiconductor device and method of manufacturing a metal interconnection structure.

### 2. Description of the Related Art

A back end of line (BEOL) followed by a front end of line (FEOL) is the process of forming an entire circuit by completing the operation of forming a direct device structure and connecting and wiring devices that perform various electrical functions.

Because devices are connected through the BEOL process, the BEOL process is an important operation in determining the performance and function of the overall integrated circuit (IC).

Recently, as semiconductor devices are minimized, the pattern width (critical dimension) of metal wiring and the gap between metal wiring are rapidly decreasing in BEOL M1 wiring, and so on. Accordingly, as the electron mean free path of metal becomes larger than the pattern width of metal wiring, problems such as increased resistivity and resistive-capacitive (RC) delay due to increased electron scattering are emerging.

To solve the resistivity increase problem and the RC delay problem, after deposition of metal wires, operations such as introducing an air gap or annealing operations may be additionally performed in subsequent processes. However, during these subsequent processes, metal wiring deteriorates or breaks.

### SUMMARY

An aspect provides a semiconductor device and a method of manufacturing a metal interconnection structure by which low resistance is realized, and deterioration and/or breakage of metal wiring is controlled.

The technical tasks to be achieved by the present example embodiments are not limited to the technical tasks described above, and other technical tasks may be inferred from the following example embodiments by those skilled in the art.

According to an aspect, there is provided a semiconductor device having an activation pattern extended in a first direction, a gate electrode having portions of the gate electrode spaced apart in the first direction on the activation pattern, and extending in a second direction intersecting the first direction, a gate contact on the gate electrode, a source/drain pattern on the activation pattern, a source/drain contact on the source/drain pattern, an insulation layer over the gate contact and the source/drain contact, a via that penetrates the insulation layer, wherein the via is on at least one of the gate contact or the source/drain contact, an adhesion layer on the insulation layer, wherein the adhesion layer exposes an upper surface of the via, and an interconnection layer on the adhesion layer, wherein the upper surface of the via is in contact with a first portion of the interconnection layer, and wherein the adhesion layer includes tantalum boride (TaB) or an alloy of TaB.

According to another aspect, there is provided a method of manufacturing a metal interconnection structure, the method including forming an adhesion layer on an insulation layer, and forming an interconnection layer on the adhesion layer, wherein the adhesion layer includes tantalum boride (TaB) or an alloy of TaB, and wherein the interconnection layer includes one or more material selected from the group consisting of Ru, Rh, Ir, Mo, Cu, Co, W, RuAl, NiAl, NbB₂, MoB₂, CuAl, CuAl₂ and MoW.

According to another aspect, there is provided a semiconductor device including an activation pattern extended in a first direction, a gate electrode having portions of the gate electrode spaced apart in the first direction on the activation pattern, and extending in a second direction intersecting the first direction, a gate contact on the gate electrode, a source/drain pattern on the activation pattern, a source/drain contact on the source/drain pattern, an insulation layer over the gate contact and the source/drain contact, a via that penetrates the insulation layer and on at least one of the gate contact or the source/drain contact, an adhesion layer on the insulation layer, wherein the adhesion layer covers an upper surface of the via, and an interconnection layer on the adhesion layer, wherein the adhesion layer includes tantalum boride (TaB) or an alloy of TaB.

Additional aspects of example embodiments will be set forth in part in the description which follows and, in part, will be apparent from the description, or may be learned by practice of the disclosure.

According to example embodiments, it is possible to achieve low resistance and control the deterioration or breakage of metal wiring with a semiconductor device and a method of manufacturing a metal interconnection structure.

### BRIEF DESCRIPTION OF THE DRAWINGS

These and/or other aspects, features, and advantages of the present disclosure will become apparent and more readily appreciated from the following description of example embodiments, taken in conjunction with the accompanying drawings of which:

FIG. 1 is a layout diagram of a semiconductor device according to an example embodiment;

FIG. 2 is a cross-sectional view taken along line A-A of FIG. 1;

FIG. 3 is a cross-sectional view taken along line B-B of FIG. 1;

FIG. 4 is a cross-sectional view taken along line C-C of FIG. 1;

FIGS. 5 to 12 are diagrams of semiconductor devices according to other example embodiments;

FIGS. 13 to 17 are diagrams of semiconductor devices according to other example embodiments;

FIGS. 18 to 21 are diagrams illustrating intermediate operations of a method of manufacturing a metal interconnection structure according to example embodiments;

FIGS. 22 and 23 are diagrams illustrating intermediate operations of a method of manufacturing a metal interconnection structure according to other example embodiments; and

FIGS. 24 to 26 are diagrams illustrating intermediate operations of a method of manufacturing a metal interconnection structure according to other example embodiments.

### DETAILED DESCRIPTION

Terms or words used in the present disclosure and claims should not be construed as limited to their ordinary or dictionary meanings. The terms or words must be interpreted with meaning and concept consistent with the technical idea of the present disclosure based on the principle that an inventor can appropriately define terminological concepts to explain his or her present disclosure.

The embodiments of the present disclosure may be modified in various different ways, all without departing from the spirit or scope of the present disclosure.

In the present disclosure, items described in the singular herein may be provided in plural, as can be seen, for example, in the drawings. Thus, the description of a single item that is provided in plural should be understood to be applicable to the remaining plurality of items unless the context clearly dictates otherwise.

Throughout the specification, when a part is described as “containing”, “comprising” or “including” a component, it does not exclude another component but may further include another component unless otherwise stated. Therefore, for example, a structure containing, including, or comprising component A may include only component A, or may further include components other than A.

The terms “equipped with” “have,” “may have,” “include,” and “may include” as used herein indicate the presence of corresponding features (for example, elements such as numerical values, functions, operations, or parts), and do not preclude the presence of additional features.

In the present disclosure, when an amount, concentration, ratio or other value or parameter is given as a range, or enumeration of upper and lower values or parameters, it should be understood as specifically disclosing all ranges that can be formed by any upper range limit or desired value and any lower range limit or desired value of a random pair regardless of whether the scope is separately disclosed. When ranges of numerical values are stated herein, unless otherwise stated, for example, unless there is a qualifying term such as greater than, less than, and so on, the range is intended to include the endpoint value and all integers and fractions within the range. The scope of the present disclosure is not intended to be limited to the specific values recited when defining the scope.

If the measurement temperature affects material properties described with a specific example embodiment among physical properties described in the present disclosure, unless otherwise specified, the physical properties are measured at room temperature. The term room temperature is the natural temperature that is not heated or cooled. For example, the term room temperature may indicate any temperature in the range of about 10° C. to 30° C., about 23° C., or about 25° C. Further, unless otherwise specified, the unit of temperature in this specification is ° C.

Further, when the measured pressure affects the material properties described with a specific example embodiment among physical properties described in the present disclosure, unless otherwise specified, the physical properties are measured at normal pressure, that is, atmospheric pressure (about 1 atmosphere).

It will be understood that when an element is referred to as being “adjacent”, “connected” to, “over” or “on” another element, it can be directly adjacent, connected to, over, or on the other element, or intervening elements may be present. In contrast, when an element is referred to as being “immediately adjacent” or “directly connected” to another element, or as “contacting” or “in contact” with another element (or using any form of the word “contact” used as a verb), there are no intervening elements present at the point of contact.

Some example drawings of a semiconductor device according to some example embodiments illustrate a Fin-type transistor (FinFET) containing a channel region in the shape of a fin-type pattern, a transistor containing nanowires or nanosheets, or a multi-bridge channel field effect transistor (MBCFET), but the present disclosure is not limited thereto. In some example embodiments, the semiconductor device may include a tunneling transistor (tunneling FET), a vertical transistor (Vertical FET), or a three-dimensional (3D) transistor. In some example embodiments, the semiconductor device may include planar transistors. In addition, the technical idea of the present disclosure can be applied to 2D material-based transistors (2D material based FETs) and their heterostructure.

Further, the semiconductor device may include a bipolar junction transistor, a horizontal double diffusion transistor (LDMOS), and so on.

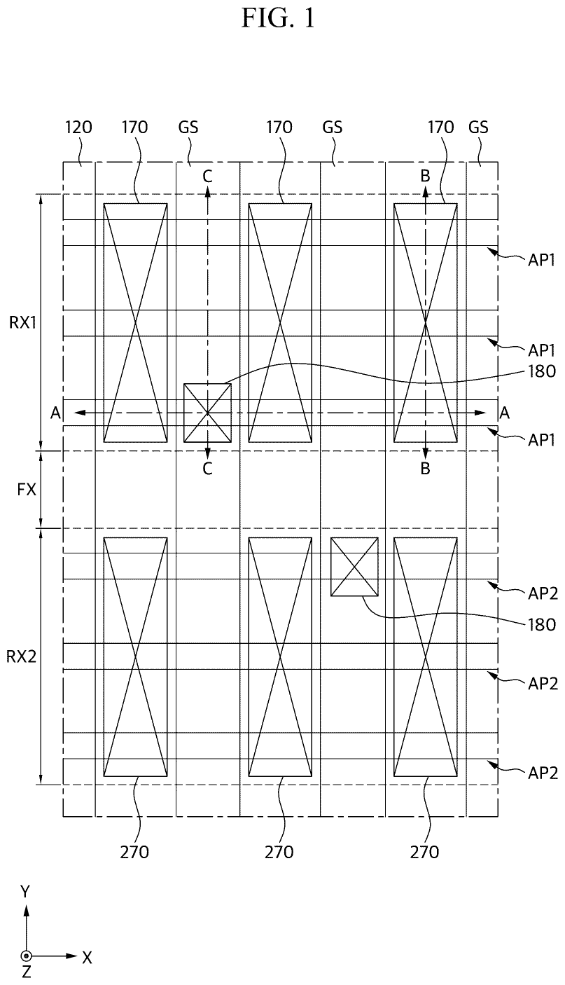

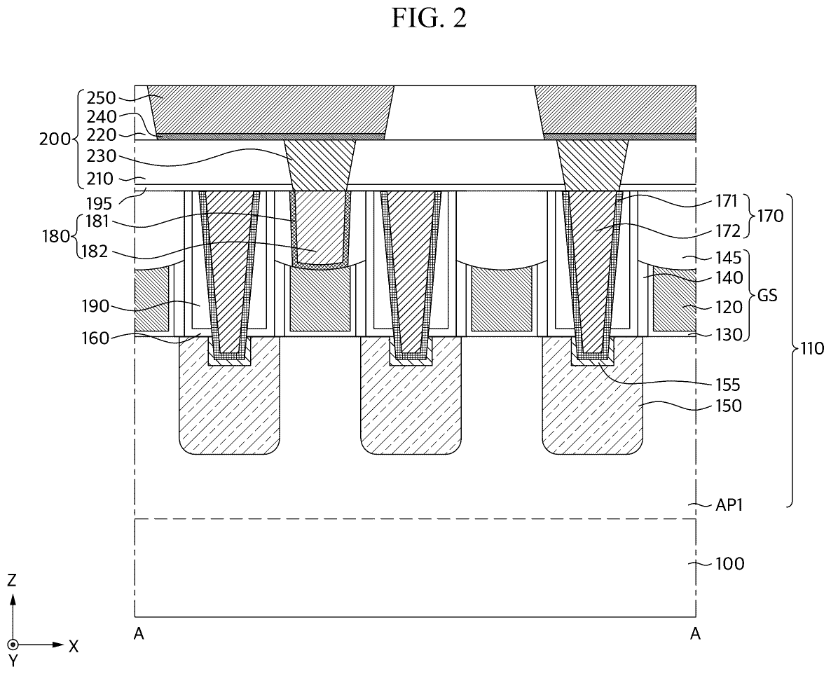

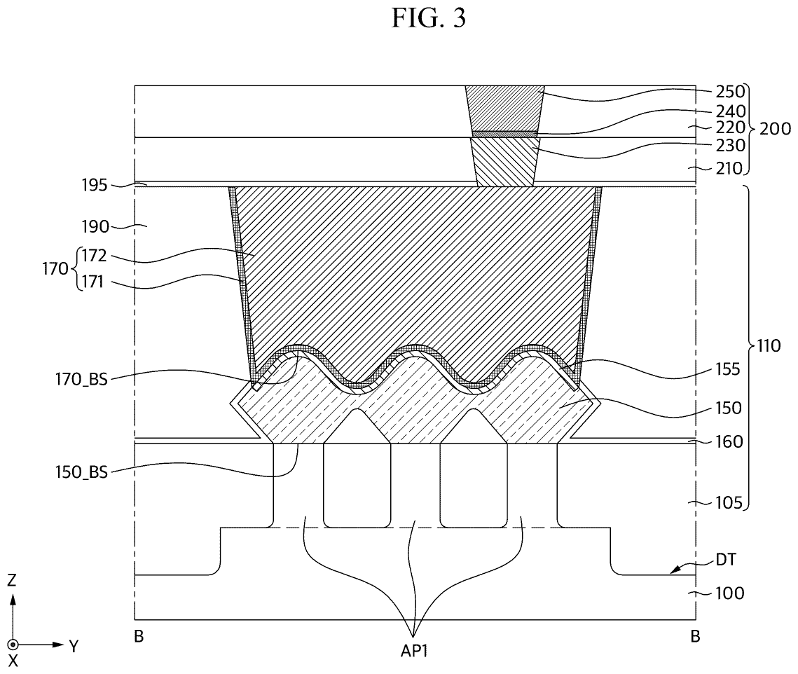

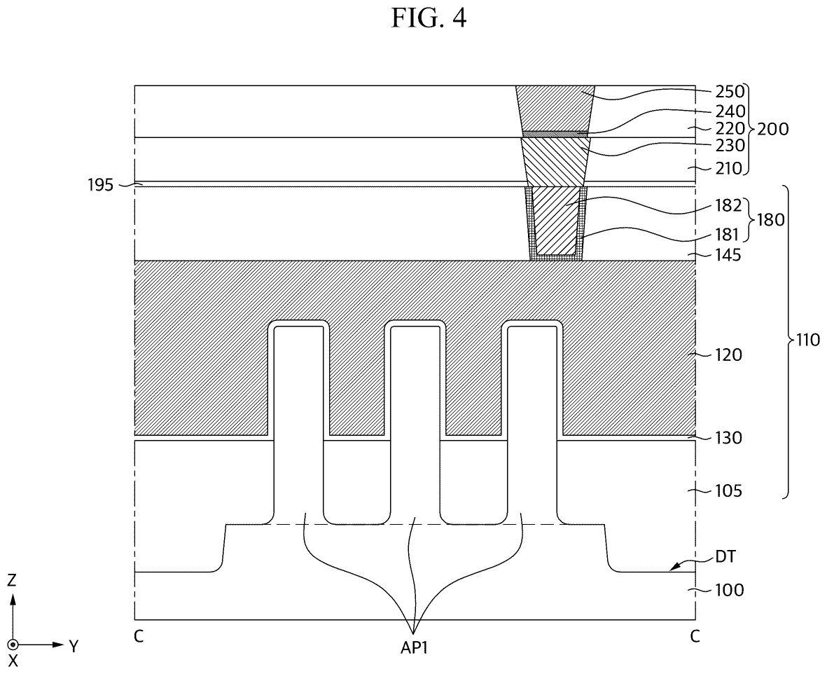

FIG. 1 is a layout diagram of a semiconductor device according to example embodiments. FIG. 2 is a cross-sectional view taken along line A-A of FIG. 1. FIG. 3 is a cross-sectional view taken along line B-B of FIG. 1. FIG. 4 is a cross-sectional view taken along line C-C of FIG. 1.

For reference, FIG. 2 illustrates that a via 230 connected to a source/drain contact 170 and the via 230 connected to a gate contact 180 are placed adjacent to each other in the first direction X on a first activation pattern AP1. However, the arrangement of via 230 is only for convenience of explanation and is not limited thereto.

Even though not illustrated, a cross-sectional view cut in the first direction X along a second activation pattern AP2 may be similar to FIG. 2 except for the positions of the via 230 and an interconnection layer 250.

Referring to FIGS. 1 to 4, the semiconductor device may include a substrate 100, a device layer 110, and a metal interconnection structure 200.

According to some example embodiments, the device layer 110 may be formed on the active surface of the substrate 100. The device layer 110 may include a plurality of various types of individual devices. The plurality of various types of individual devices may include various micro electronic devices, such as metal-oxide-semiconductor field effect transistors (MOSFETs) such as complementary metal-oxide semiconductor (CMOS) transistors, system large scale integration (LSI), image sensors such as CMOS imaging sensors (CIS), a micro-electro-mechanical system (MEMS), active and passive elements and so on. The plurality of individual devices may be electrically connected to the conductive area of the substrate 100. Further, each of the plurality of individual devices may be electrically separated from other neighboring individual devices by an insulating film.

According to some example embodiments, the metal interconnection structure 200 may be applied to M1 layer of the back-end-of-line (BEOL). The metal interconnection structure 200 may be formed, for example, on the surface of the device layer 110. More specifically, the lower surface of a first insulation layer 210 of the metal interconnection structure 200 may be formed on the surface of the device layer 110. The first insulation layer 210 of the metal interconnection structure 200 may further include a device layer etch stopping film 195 on the lower surface in contact with the surface of the device layer 110. However, the first insulation layer 210 may electrically connect the device layer 110 to an adhesion layer 240 and/or the interconnection layer 250 through the via 230. In another example embodiment, the metal interconnection structure 200 may be applied to M3 layer of the BEOL.

According to some example embodiments, the semiconductor device may be applied to a memory semiconductor or a logic semiconductor. For example, the memory semiconductor may be a volatile memory semiconductor such as Dynamic Random Access Memory (DRAM) or Static Random Access Memory (SRAM), or may be a non-volatile memory semiconductor such as Phase-change Random Access Memory (PRAM), Magnetoresistive Random Access Memory (MRAM), Ferroelectric Random Access Memory (FeRAM), or Resistive Random Access Memory (RRAM). Further, the logic semiconductor may be, for example, a microprocessor, an analog device, or a digital signal processor.

According to some example embodiments, the device layer 110 may include at least one first activation pattern AP1, at least one second activation pattern AP2, at least one first gate electrode 120, the source/drain contact 170, a second source/drain contact 270 and the gate contact 180.

According to some example embodiments, as shown in FIG. 1, the substrate 100 may include a first active region RX1, a second active region RX2 and a field region FX. The field region FX may be formed immediately adjacent to the first active region RX1 and the second active region RX2. The field region FX may be bordered by the first active region RX1 and the second active region RX2.

According to some example embodiments, the first active region RX1 and the second active region RX2 are spaced apart from each other. The first active region RX1 and the second active region RX2 may be spaced apart by the field region FX.

In example embodiments, a device isolation layer may be placed around the first active region RX1 and the second active region RX2, which are spaced apart from each other. In FIG. 1, with respect to the device isolation layer, the part between the first active region RX1 and the second active region RX2 may be the field region FX. For example, a portion where the channel region of a transistor, which can be an example of a semiconductor device, is formed may be an active region, and a field region may be a portion that separates the channel region of the transistor formed in the active region. Alternatively, the active region may be a fin-shaped pattern used as a channel region of a transistor or a portion where a nanosheet is formed, and the field region may be a fin-shaped pattern used as a channel region or a region in which nanosheets are not formed.

As illustrated in FIGS. 3 and 4, the field region FX (from FIG. 1) may be defined by, but is not limited to, a deep trench DT. A person skilled in the art to which the present disclosure pertains can distinguish which part is the field region and which part is the active region.

According to some example embodiments, one of the first active region RX1 and the second active region RX2 may be a PMOS formation region, and the other one may be an NMOS formation region. In another example embodiment, the first active region RX1 and the second active region RX2 may be PMOS formation regions. In another example embodiment, the first active region RX1 and the second active region RX2 may be NMOS formation regions.

According to some example embodiments, the substrate 100 may be a silicon substrate or a silicon-on-insulator (SOI). Alternatively, the substrate 100 may include silicon-germanium, silicon germanium on insulator (SGOI), indium antimonide, lead tellurium compound, indium arsenide, indium phosphide, gallium arsenide, or gallium antimonide, but the substrate 100 is not limited thereto.

According to some example embodiments, the substrate 100 may include a group IV element such as silicon (Si) and germanium (Ge), group IV-IV compounds such as silicon-germanium (SiGe) and silicon carbide (SiC), or group III-V compounds such as gallium arsenide (GaAs), indium arsenide (InAs) and indium phosphide (InP). The substrate 100 may include a conductive region, for example, a well doped with impurities. The substrate 100 may have various device isolation structures, such as a shallow trench isolation (STI) structure. The substrate 100 may have an active surface and an inactive surface opposite to the active surface.

According to some example embodiments, at least one first activation pattern AP1 may be formed in the first active region RX1 (see e.g., FIG. 1). The first activation pattern AP1 may protrude from the substrate 100 of the first active region RX1. The first activation pattern AP1 may extend long along the first direction X on the substrate 100. For example, the first activation pattern AP1 may include a long side extending in the first direction X and a short side extending in the second direction Y. Here, the first direction X may intersect the second direction Y and the third direction Z. Further, the second direction Y may intersect the third direction Z. The third direction Z may be the thickness direction of the substrate 100.

According to some example embodiments, at least one second activation pattern AP2 may be formed in the second active region RX2. The description regarding the second activation pattern AP2 may be substantially the same as the description regarding the first activation pattern AP1.

According to some example embodiments, each of the first activation pattern AP1 and the second activation pattern AP2 may be a multi-channel activation pattern. In the semiconductor device according to some example embodiments, each of the first activation pattern AP1 and the second activation pattern AP2 may be, for example, a fin-type pattern. Each of the first activation pattern AP1 and the second activation pattern AP2 may be used as the channel region of the transistor. It is illustrated in FIG. 1 that there are three first activation patterns AP1 and three second activation patterns AP2, but the illustration is only for convenience of explanation, and the present disclosure is not limited thereto. There may be more than one first activation pattern AP1 and more than one second activation pattern AP2.

According to some example embodiments, each of the first activation pattern AP1 and the second activation pattern AP2 may be part of the substrate 100, and may each include an epitaxial layer grown from the substrate 100. The first activation pattern AP1 and the second activation pattern AP2 may include, for example, silicon or germanium which is an elemental semiconductor material. Further, the first activation pattern AP1 and the second activation pattern AP2 may include a compound semiconductor. For example, the first activation pattern AP1 and the second activation pattern AP2 may include a group IV-IV compound semiconductor or a group III-V compound semiconductor.

For example, the group IV-IV compound semiconductor may be a binary compound or a ternary compound containing at least two elements selected from the group consisting of carbon (C), silicon (Si), germanium (Ge) and tin (Sn), or may be a compound in which the binary compound or the ternary compound is doped with a group IV element.

For example, the group III-V compound semiconductor may be one of a binary compound, a ternary compound and a quaternary compound, which is formed by combining at least one of the group III elements aluminum (Al), gallium (Ga) or indium (In), with one of the group V elements phosphorus (P), arsenic (As) or antimonium (Sb).

According to some example embodiments, the first activation pattern AP1 and the second activation pattern AP2 may contain the same substance. For example, each of the first activation pattern AP1 and the second activation pattern AP2 may be a silicon fin-type pattern. Alternatively, for example, each of the first activation pattern AP1 and the second activation pattern AP2 may be a fin-type pattern including a silicon-germanium pattern. In another example embodiment, the first activation pattern AP1 and the second activation pattern AP2 may contain different substances. For example, the first activation pattern AP1 may be a silicon fin-type pattern, and the second activation pattern AP2 may be a fin-type pattern including a silicon-germanium pattern.

According to some example embodiments, a field insulation film 105 may be formed on the substrate 100. The field insulation film 105 may be formed over the first active region RX1, the second active region RX2 and the field region FX. The field insulation film 105 may fill the deep trench DT.

According to some example embodiments, the field insulation film 105 may cover the sidewall of the first activation pattern AP1 and the sidewall of the second activation pattern AP2. Each of the first activation pattern AP1 and the second activation pattern AP2 may protrude above the upper surface of the field insulation film 105. The field insulation film 105 may include, for example, an oxide film, a nitride film, an oxynitride film, or a combination thereof.

According to some example embodiments, at least one gate structure GS may be disposed on the substrate 100. For example, at least one gate structure GS may be disposed on the field insulation film 105. The gate structure GS may extend in the second direction Y. The adjacent gate structures GS may be spaced apart in the first direction X.

According to some example embodiments, the gate structure GS may be placed on the first activation pattern AP1 and the second activation pattern AP2. The gate structure GS may intersect with the first activation pattern AP1 and the second activation pattern AP2.

According to some example embodiments, it is illustrated that the gate structure GS is arranged across the first active region RX1 and the second active region RX2, but it is only for convenience of explanation, and the present disclosure is not limited thereto. In example embodiments, a part of the gate structure GS may be separated into two parts by a gate separation structure disposed on the field insulation film 105, and be disposed on the first active region RX1 and the second active region RX2.

According to some example embodiments, the gate structure GS may include, for example, the gate electrode 120, a gate insulation film 130, a gate spacer 140, and a gate capping layer 145.

According to some example embodiments, the gate electrode 120 may be placed on the first activation pattern AP1 and the second activation pattern AP2. The gate electrode 120 may intersect with the first activation pattern AP1 and the second activation pattern AP2. The gate electrode 120 may cover the first activation pattern AP1 and the second activation pattern AP2 that protrude more than the upper surface of the field insulation film 105. The gate electrode 120 may include a long side extending in the second direction Y and a short side extending in the first direction X.

According to some example embodiments, the upper surface of the gate electrode 120 may be a concave curved surface that is recessed toward the upper surface of the first activation pattern AP1, but the upper surface is not limited thereto. Unlike what is illustrated, the upper surface of the gate electrode 120 may be a flat plane in example embodiments.

According to some example embodiments, for example, the gate electrode 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), Osmium (Os), silver (Ag), gold (Au), zinc (Zn), or vanadium (V), or a combination thereof.

According to some example embodiments, each gate electrode 120 may include conductive metal oxide, conductive metal oxynitride, and so on, and may include an oxidized form of the above-described material.

According to some example embodiments, the gate electrode 120 may be placed on both sides of a source/drain pattern 150, described herein. The gate structure GS may be disposed on both sides of the source/drain pattern 150 in the first direction X.

According to some example embodiments, the gate electrodes 120 disposed on both sides of the source/drain pattern 150 may be normal gate electrodes used as gates of transistors. In another example embodiment, the gate electrode 120 disposed on one side of the source/drain pattern 150 is used as the gate of the transistor, but the gate electrode 120 disposed on the other side of the source/drain pattern 150 may be a dummy gate electrode.

According to some example embodiments, the gate spacer 140 may be disposed on the sidewall of the gate electrode 120. The gate spacer 140 may extend in the second direction Y. For example, the gate spacer 140 may include at least one of silicon nitride (SiN), silicon oxynitride (SiON), silicon oxide (SiO₂), silicon oxycarbonitride (SiOCN), silicon boronitride (SiBN), silicon oxyboron nitride (SiOBN), or silicon oxycarbide (SiOC), or a combination thereof.

According to some example embodiments, the gate insulation film 130 may extend along the sidewall and the bottom surface of the gate electrode 120. The gate insulation film 130 may be formed on the first activation pattern AP1, the second activation pattern AP2 and the field insulation film 105. The gate insulation film 130 may be formed between the gate electrode 120 and the gate spacer 140.

According to some example embodiments, the gate insulation film 130 may be formed along the upper surface of the field insulation film 105. The gate insulation film 130 may be formed according to the profile of the first activation pattern AP1 that protrudes above the field insulation film 105.

According to some example embodiments, the gate insulation film 130 may include silicon oxide, silicon oxynitride, silicon nitride, or a high dielectric constant material with a higher dielectric constant than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

According to some example embodiments, the gate insulation film 130 is illustrated as a single film, but this is only for convenience of explanation, and the gate insulation film 130 is not limited thereto. The gate insulation film 130 may include multiple films. The gate insulation film 130 may include an interfacial layer disposed between the first activation pattern AP1 and the gate electrode 120 and, between the second activation pattern AP2 and the gate electrode 120, and a high dielectric constant insulating film. For example, the interfacial layer may be formed according to the profile of the first activation pattern AP1 and the profile of the second activation pattern AP2 that protrude above the field insulation film 105.

According to some example embodiments, the semiconductor device may include a negative capacitance (NC) FET using a negative capacitor. For example, the gate insulation film 130 may include a ferroelectric material film with ferroelectric properties and a paraelectric material film with paraelectric properties.

The ferroelectric material film may have a negative capacitance, and the paraelectric material film may have a positive capacitance. For example, when two or more capacitors are connected in series and the capacitance of each capacitor has a positive value, the total capacitance is less than the capacitance of each individual capacitor. On the other hand, when at least one of the capacitances of the two or more capacitors connected in series has a negative value, the total capacitance may have a positive value, and may be greater than the absolute value of each individual capacitance.

When the ferroelectric material film with negative capacitance and the paraelectric material film with positive capacitance are connected in series, the total capacitance value of the ferroelectric material film and the paraelectric material film connected in series may increase. By taking advantage of the total capacitance value increasing, a transistor containing the ferroelectric material film may have a subthreshold swing (SS) of less than 60 m V/decade at room temperature.

The ferroelectric material film may have ferroelectric properties. For example, the ferroelectric material film may include at least one of hafnium oxide, hafnium zirconium oxide, barium strontium titanium oxide, barium titanium oxide or lead zirconium titanium oxide. Here, in an example embodiment, hafnium zirconium oxide may be a material in which zirconium (Zr) is doped into hafnium oxide. In another example embodiment, hafnium zirconium oxide may be a compound of hafnium (Hf), zirconium (Zr) and oxygen (O).

The ferroelectric material film may further include dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). Depending on what ferroelectric material the ferroelectric material film contains, the type of dopant included in the ferroelectric material film may vary.

If the ferroelectric material film contains hafnium oxide, the dopant included in the ferroelectric material film may include, for example, at least one of gadolinium (Gd), silicon (Si), zirconium (Zr), aluminum (Al) or yttrium (Y).

When the dopant is aluminum (Al), the ferroelectric material film may contain 3 to 8 atomic % (at %) of aluminum. Here, the ratio of dopant may be the ratio of aluminum to the sum of hafnium and aluminum.

When the dopant is silicon (Si), the ferroelectric material film may contain 2 to 10 at % of silicon. When the dopant is yttrium (Y), the ferroelectric material film may contain 2 to 10 at % of yttrium. When the dopant is gadolinium (Gd), the ferroelectric material film may contain 1 to 7 at % of gadolinium. When the dopant is zirconium (Zr), the ferroelectric material film may contain 50 to 80 at % of zirconium.

The paraelectric material film may have paraelectric properties. The paraelectric material film may include, for example, at least one of silicon oxide or a metal oxide having a high dielectric constant. The metal oxide included in the paraelectric material film may include, for example, at least one of hafnium oxide, zirconium oxide or aluminum oxide, but the metal oxide is not limited thereto.

The ferroelectric material film and the paraelectric material film may include the same material. The ferroelectric material film may have ferroelectric properties, but the paraelectric material film may not have ferroelectric properties. For example, when the ferroelectric material film and the paraelectric material film contain hafnium oxide, the crystal structure of hafnium oxide contained in the ferroelectric material film is different from the crystal structure of hafnium oxide contained in the paraelectric material film.

The ferroelectric material film may have a thickness that has ferroelectric properties. The thickness of the ferroelectric material film may be, for example, 0.5 to 10 nm, but is not limited thereto. The threshold thickness that exhibits ferroelectric properties may vary for each ferroelectric material, and thus the thickness of the ferroelectric material film may vary depending on the ferroelectric material.

According to some example embodiments, the gate insulation film 130 may include one ferroelectric material film. In another example embodiment, the gate insulation film 130 may include a plurality of ferroelectric material films spaced apart from each other. The gate insulation film 130 may have a laminated film structure in which a plurality of ferroelectric material films and a plurality of paraelectric material films are alternately stacked.

According to some example embodiments, the gate capping layer 145 may be disposed on the upper surface of the gate electrode 120 and the upper surface of the gate spacer 140. The upper surface of the gate capping layer 145 may be the upper surface of the gate structure GS. For example, the gate capping layer 145 may include at least one of silicon nitride (SiN), silicon oxynitride (SiON), silicon oxide (SiO₂), silicon carbonitride (SiCN), or silicon oxycarbonitride (SiOCN), or a combination thereof.

Unlike what is illustrated in the figures, according to example embodiments, the gate capping layer 145 may be placed between the gate spacers 140. In this case, the upper surface of the gate capping layer 145 may be coplanar with the upper surface of the gate spacer 140. In this case, the upper surface of the gate structure GS may include the upper surface of the gate capping layer 145 and the upper surface of the gate spacer 140.

According to some example embodiments, the source/drain pattern 150 may be located on the substrate 100. The source/drain pattern 150 may be formed on the first activation pattern AP1. The source/drain pattern 150 may be connected to the first activation pattern AP1. A bottom surface 150_BS of the first source/drain pattern contacts the first activation pattern AP1.

According to some example embodiments, the source/drain pattern 150 may be disposed on the side of the gate structure GS. For example, the source/drain pattern 150 may be disposed between the gate structures GS in the first direction X.

According to some example embodiments, the source/drain pattern 150 may be disposed on both sides of the gate structure GS. Unlike what is illustrated, the source/drain pattern 150 may be disposed on one side of the gate structure GS and may not be disposed on the other side of the gate structure GS.

According to some example embodiments, the source/drain pattern 150 may include an epitaxial pattern. The source/drain pattern 150 may include a semiconductor material. The source/drain pattern 150 may be included in the source/drain of the transistor using the first activation pattern AP1 as the channel region.

According to some example embodiments, the source/drain pattern 150 may be connected to the channel area used as a channel in the first activation pattern AP1. It is illustrated that the source/drain pattern 150 is a merge of the three epitaxial patterns formed on each first activation pattern AP1, but it is only for convenience of explanation, and the source/drain pattern 150 is not limited thereto. In example embodiments, the epitaxial patterns formed on each first activation pattern AP1 may be separated from each other.

According to some example embodiments, an air gap AG may be formed in the space between the field insulation film 105 and the source/drain pattern 150 combined. In another example embodiment, an insulating material may be filled in the space between the field insulation film 105 and the source/drain pattern 150 combined.

Although not illustrated, a source/drain pattern as described above may be placed on the second activation pattern AP2 between the gate structures GS.

According to some example embodiments, a source/drain etch stopping film 160 may extend along the upper surface of the field insulation film 105, the sidewall of the gate structure GS, and the profile of the source/drain pattern 150. The source/drain etch stopping film 160 may be placed on the upper surface of the source/drain pattern 150 and the sidewall of the source/drain pattern 150.

According to some example embodiments, the source/drain etch stopping film 160 may include a material having etching selectivity to an interlayer insulation film 190, which will be described later. For example, the source/drain etch stopping film 160 may include at least one of silicon nitride (SiN), silicon oxynitride (SiON), silicon oxycarbonitride (SiOCN), silicon boron nitride (SiBN), silicon oxyboron nitride (SiOBN), or silicon oxycarbide (SiOC), or a combination thereof.

According to some example embodiments, the interlayer insulation film 190 may be disposed on the source/drain etch stopping film 160. The interlayer insulation film 190 may be formed on the field insulation film 105. The interlayer insulation film 190 may be disposed on the source/drain pattern 150. The interlayer insulation film 190 may be disposed between the source/drain etch stopping film 160 and the source/drain contact 170.

According to some example embodiments, the interlayer insulation film 190 may not cover the upper surface of the gate structure GS. For example, the upper surface of the interlayer insulation film 190 may be coplanar with the upper surface of the gate structure GS.

According to some example embodiments, the interlayer insulation film 190 may include at least one of silicon oxide, silicon nitride, silicon oxynitride, and a low dielectric constant material. For example, the low dielectric constant material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels or mesoporous silica, or a combination thereof. However, the present disclosure is not limited thereto.

According to some example embodiments, the source/drain contact 170 may be placed on the first active region RX1. The second source/drain contact 270 may be placed on the second active region RX2. The source/drain contact 170 may be connected to the source/drain pattern 150 formed in the first active region RX1. Although not illustrated, the second source/drain contact 270 may be connected to the source/drain pattern formed in the second active region RX2.

According to some example embodiments, unlike what is illustrated in the figures, a part of the source/drain contact 170 may be directly connected to a part of the second source/drain contact 270. According to some example embodiments, at least one source/drain contact may be placed over the first active region RX1 and the second active region RX2 in the semiconductor device.

According to some example embodiments, matters regarding the second source/drain contact 270 are substantially the same as the matters concerning the source/drain contact 170, and thus the following explanation uses the source/drain contact 170 on the first activation pattern AP1.

According to some example embodiments, the gate contact 180 may be disposed within the gate structure GS. The gate contact 180 may be connected to the gate electrode 120 included in the gate structure GS.

According to some example embodiments, the gate contact 180 may be disposed at a position that overlaps the gate structure GS. According to some example embodiments, in the semiconductor device, at least a portion of the gate contact 180 may be disposed in a position overlapping at least one of the first active region RX1 or the second active region RX2. For example, from a plan view perspective, the gate contact 180 may be disposed in a position that overlaps the first active region RX1 or the second active region RX2.

According to some example embodiments, the source/drain contact 170 may be connected to the source/drain pattern 150 by passing through the source/drain etch stopping film 160. The source/drain contact 170 may be placed on the source/drain pattern 150.

According to some example embodiments, the source/drain contact 170 may be disposed within the interlayer insulation film 190. The source/drain contact 170 may be surrounded by the interlayer insulation film 190.

According to some example embodiments, a contact silicide film 155 may be disposed between the source/drain contact 170 and the source/drain pattern 150. It is illustrated that the contact silicide film 155 is formed along the profile of the interface between the source/drain pattern 150 and the source/drain contact 170, but the contact silicide film 155 is not limited thereto. The contact silicide film 155 may include, for example, a metal silicide material.

According to some example embodiments, the interlayer insulation film 190 does not cover the upper surface of the source/drain contact 170. In an example embodiment, the upper surface of the source/drain contact 170 may not protrude above the upper surface of the gate structure GS. The upper surface of the source/drain contact 170 may be coplanar with the upper surface of the gate structure GS. In another example embodiment, the upper surface of the source/drain contact 170 may protrude above the upper surface of the gate structure GS.

According to some example embodiments, the source/drain contact 170 may include a source/drain contact barrier film 171 and a source/drain contact filling film 172 on the source/drain contact barrier film 171. The source/drain contact barrier film 171 may extend along the sidewall and the bottom surface of the source/drain contact filling film 172.

It is illustrated that a bottom surface of the source/drain contact 170_BS has a wavy shape according to some example embodiments, but the embodiments are not limited thereto. Unlike what is illustrated, the bottom surface of the source/drain contact 170_BS may also have a flat shape.

It is illustrated that based on the upper surface of the first activation pattern AP1, the upper surface of the source/drain contact barrier film 171 is located at the same level or substantially the same level as the upper surface of the source/drain contact filling film 172 according to some example embodiments, but the present invention is not limited thereto.

Based on the upper surface of the first activation pattern AP1, the upper surface of the source/drain contact barrier film 171 may be lower than the upper surface of the source/drain contact filling film 172.

According to some example embodiments, the source/drain contact barrier film 171 may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), or rhodium (Rh) and a two-dimensional (2D) material. In the semiconductor according to some example embodiments, the 2D material may be a metallic material and/or a semiconductor material. The 2D material may include a 2D allotrope or a 2D compound. For example, at least one of graphene, molybdenum disulfide (MoS2), molybdenum diselenide (MoSe₂), tungsten diselenide (WSe₂) or tungsten disulfide (WS₂) may be included, but the present disclosure is not limited thereto. The described materials are examples, and thus 2D materials that can be included in the semiconductor are not limited the above described materials.

According to some example embodiments, the source/drain contact filling film 172 may include at least one of aluminum (Al), tungsten (W), cobalt (Co), ruthenium (Ru), silver (Ag), gold (Au), manganese (Mn) or molybdenum (Mo).

It is illustrated that the source/drain contact 170 includes a plurality of conductive films according to some example embodiments, but the source/drain contact 170 is not limited thereto. Unlike what is illustrated, the source/drain contact 170 may be a single layer.

According to some example embodiments, the gate contact 180 may be disposed on the gate electrode 120. The gate contact 180 may penetrate (or be positioned through) the gate capping layer 145 and be connected to the gate electrode 120.

According to some example embodiments, the upper surface of the gate contact 180 may be coplanar with the upper surface of the gate structure GS. Specifically, the upper surface of the gate contact 180 may be coplanar with the upper surface of the gate capping layer 145. In another example embodiment (not pictured), the upper surface of the gate contact 180 may protrude above the upper surface of the gate structure GS.

According to some example embodiments, the gate contact 180 may include a gate contact barrier film 181 and a gate contact filling film 182 on the gate contact barrier film 181. The description regarding the materials included in the gate contact barrier film 181 and the gate contact filling film 182 may be the same as the description regarding the source/drain contact barrier film 171 and the source/drain contact filling film 172.

According to some example embodiments, the device layer etch stopping film 195 may be disposed on the interlayer insulation film 190, the gate structure GS, the source/drain contact 170, and the gate contact 180. The device layer etch stopping film 195 may be at a bottom part of the first insulation layer 210. The device layer etch stopping film 195 may be extended along the bottom surface of the first insulation layer 210.

According to some example embodiments, the device layer etch stopping film 195 may include a material having etching selectivity to the first insulation layer 210. For example, the device layer etch stopping film 195 may include at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AlO), aluminum nitride (AlN), or aluminum oxycarbide (AlOC), or a combination thereof. It is illustrated that the device layer etch stopping film 195 is a single layer, but the device layer etch stopping film 195 is not limited thereto. In example embodiments, the device layer etch stopping film 195 may not be formed.

According to some example embodiments, the metal interconnection structure 200 may be disposed on the device layer 110. The metal interconnection structure 200 may include the first insulation layer 210, a second insulation layer 220, the via 230, the adhesion layer 240, and the interconnection layer 250.

According to some example embodiments, the first insulation layer 210 and the second insulation layer 220 may be sequentially placed on the device layer etch stopping film 195, in that order. The first insulation layer 210 may be disposed on or over the source/drain contact 170 and the gate contact 180. According to example embodiments, the first insulation layer may be generally over the source/drain contact and the gate electrode in the Z direction. It should be understood that portions of the first insulation layer may not be over all portions of the source/drain contact and the gate electrode in the X direction and the Y direction. Additionally, there may be other elements between the source/drain contact and the first insulation layer, and between the gate electrode and the first insulation layer.

The second insulation layer 220 may extend along the upper surface of the first insulation layer 210. For example, the first insulation layer 210 and the second insulation layer 220 may include at least one of silicon oxide, silicon nitride, silicon carbonitride, silicon oxynitride, or insulating polymer or low dielectric constant material.

According to some example embodiments, the via 230 may be placed within the first insulation layer 210. The via 230 may penetrate the first insulation layer 210, or be positioned through or within the first insulation layer 210. The first insulation layer 210 may surround the via 230. The via 230 may penetrate the device layer etch stopping film 195 and be directly connected to the source/drain contact 170 and the gate contact 180.

According to some example embodiments, the via 230 may include at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), or rhodium (Rh) or a 2D material. Further, in an example embodiment, the via 230 may include at least one of aluminum (Al), tungsten (W), cobalt (Co), ruthenium (Ru), copper (Cu), silver (Ag), gold (Au), or manganese (Mn) or molybdenum (Mo).

According to some example embodiments, the via 230 may include one or more material selected from the group consisting of W, Ti, TiN, Mo, Ru, Rh, Ir, Cu, Co, RuAl, NiAl, NbB₂, MoB₂ and MoW. The via 230 may be composed of only one material selected from the group consisting of W, Ti, TiN, Mo, Ru, Rh, Ir, Cu, Co, RuAl, NiAl, NbB₂, MoB₂, and MoW, or may include two or more materials selected from the group consisting of W, Ti, TiN, Mo, Ru, Rh, Ir, Cu, Co, RuAl, NiAl, NbB₂, MoB₂ and MoW forming a multi-layer structure in the vertical direction.

According to some example embodiments, the adhesion layer 240 may be disposed on the first insulation layer 210 and the via 230. The adhesion layer 240 may extend along at least a portion of the upper surface of the first insulation layer 210. The adhesion layer 240 may connect the via 230 and the interconnection layer 250.

The adhesion layer 240 may have a width in the second direction Y. The width (critical dimension) of the adhesion layer 240 may be 10 nm or less. For example, at the same level as the upper surface of the first insulation layer 210, the adhesion layer 240 has a maximum width, and the maximum width may be 10 nm or less.

FIGS. 3 and 4 illustrate that in the second direction Y, only one adhesion layer 240 is disposed, but the present disclosure is not limited thereto. For example, a plurality of adhesion layers 240 may be arranged in the width direction (the second direction Y). Among the plurality of adhesion layers 240, the distance between the adjacent adhesion layers 240 may be for example, 10 nm or less.

According to some example embodiments, the adhesion layer 240 may include TaB or an alloy of TaB. The adhesion layer 240 may prevent the interconnection layer 250 from deteriorating or disconnecting from the via 230.

According to some example embodiments, with respect to the adhesion layer 240, the molar ratio of B to Ta (N_{B}/N_{Ta}) is 5/95 to 30/70. In another example embodiment, the adhesion layer 240 may have a molar ratio of B to Ta (N_{B}/N_{Ta}) of 7/93 or higher, 9/91 or higher or 11/89 or higher, 25/85 or lower, 20/80 or lower, or 15/85 or lower. As the adhesion layer 240 contains Ta and B in the molar ratio, the adhesion layer resistance characteristics may be improved.

According to some example embodiments, the alloy of TaB included in the adhesion layer 240 may be an alloy of TaB and one or more elements selected from the group consisting of Ru, Mo, Cu, Al and Pt. To improve adhesion layer resistance, the TaB alloy may be an alloy of Ru and TaB. With regard to the alloy of TaB, the molar ratio between TaB and one or more elements selected from the group consisting of Ru, Mo, Cu, Al and Pt, may be controlled to 30/70 to 70/30.

According to some example embodiments, the adhesion layer 240 may have a single-layer structure or a multi-layer structure. For example, the adhesion layer 240 may have a multi-layer structure in which TaB or its alloy, and one or more material selected from the group consisting of Ru, Rh, Ir, Mo, Cu, Co, W, RuAl, NiAl, NbB₂, MoB₂ and MoW, are alternately laminated. For the realization of low resistance through interaction between the adhesion layer and the interconnection layer and for the control of deterioration or breakage of metal wiring, according to example embodiments, the adhesion layer may have a multi-layer structure in which TaB and Ru are alternately stacked.

According to some example embodiments, the thickness of the adhesion layer 240 may be 20% or less compared to the thickness of the interconnection layer 250. In the present disclosure, when the adhesion layer 240 has a single-layer structure, the thickness of the adhesion layer 240 may refer to the thickness of the single layer, and when the adhesion layer 240 has a multi-layer structure, the thickness of the adhesion layer 240 may indicate the sum of the thicknesses of all layers constituting the adhesion layer 240.

According to some example embodiments, the thickness of the adhesion layer 240 may be 10 to 50 Å. For example, the distance from the upper surface of the via 230 or the upper surface of the first insulation layer 210 to the upper surface of the adhesion layer 240 may be 10 to 50 Å.

According to some example embodiments, the interconnection layer 250 may be placed on the adhesion layer 240. A plurality of interconnection layers may be arranged by being spaced apart on the adhesion layer in the first direction X or in the second direction Y. The interconnection layer 250 may be placed within the second insulation layer 220. The interconnection layer 250 may be electrically connected to the via 230. The interconnection layer 250 may contact the via 230.

FIG. 2 illustrates that the interconnection layer 250 is a single layer, but the interconnection layer 250 is not limited thereto. For example, the interconnection layer 250 may include an interconnection barrier film and an interconnection filling film. The interconnection barrier film may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), or rhodium (Rh) or a 2D material. For example, each interconnection filling film may include at least one of aluminum (Al), copper (Cu), tungsten (W), cobalt (Co), ruthenium (Ru), silver (Ag), gold (Au), manganese (Mn) or molybdenum (Mo).

According to some example embodiments, the interconnection layer 250 may include the same material as the via. For example, the interconnection layer 250 may include one or more material selected from the group consisting of Ru, Rh, Ir, Mo, Cu, Co, W, RuAl, NiAl, NbB₂, MoB₂, CuAl, CuAl₂ and MoW. To achieve low resistance, the interconnection layer 250 may include a metal with a low resistivity scaling factor. Further, the interconnection layer 250 may include one or more material selected from the group consisting of Ru, Mo, NiAl, CuAl, CuAl₂ and RuAl. More specifically, the interconnection layer 250 may include Ru.

In Example embodiments (not shown), a first connection contact connecting the via 230 and the source/drain contact 170 may be further disposed between the via 230 and the source/drain contact 170. Further, a second connection contact connecting the via 230 and the gate contact 180 may be further disposed between the via 230 and the gate contact 180.

FIGS. 2 to 4 illustrate that the adhesion layer 240 and the interconnection layer 250 extend in the first direction X and have the width in the second direction Y, but the adhesion layer 240 and the interconnection layer 250 are not limited thereto. For example, the adhesion layer 240 and the interconnection layer 250 may extend in the second direction Y and have the width in the first direction X.

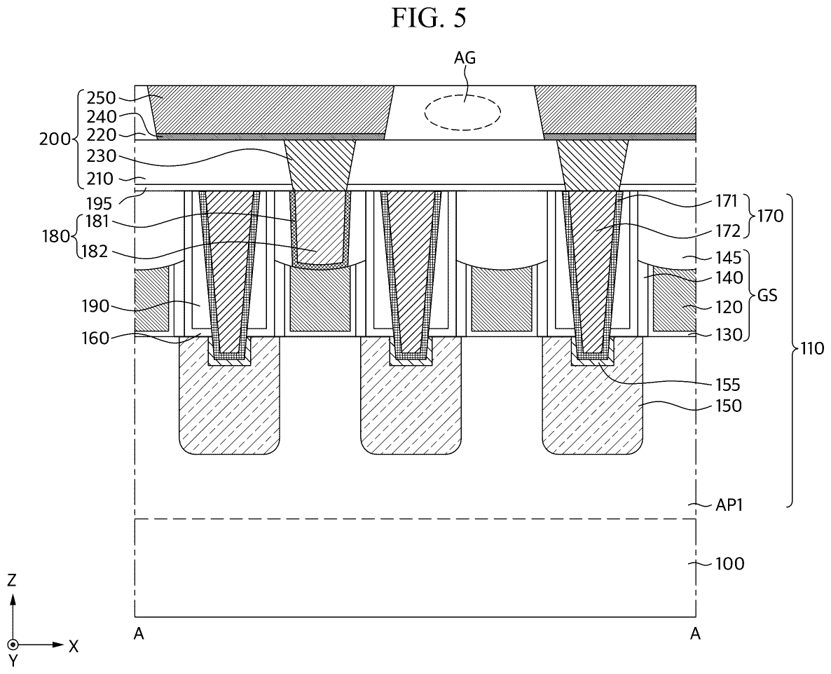

FIGS. 5 to 12 are diagrams of semiconductor devices according to other example embodiments. For convenience of explanation, description will focus on differences from the descriptions with reference to FIGS. 1 to 4.

Referring to FIG. 5, an air gap AG may be between the interconnection layers 250 spaced apart from each other. The air gap AG may be disposed in the second insulation layer 220 where the interconnection layer 250 is disposed. The second insulation layer 220 may include the air gap AG.

For example, the air gap AG may accommodate air inside. For another example, the air gap AG may contain process gases used in the process of manufacturing a semiconductor device. The air gap AG is a gap defined by a surrounding insulating film, and has a lower dielectric constant than materials such as silicon oxide. Accordingly, parasitic capacitance between the interconnection layers 250 may be reduced. As the parasitic capacitance between the interconnection layers 250 is reduced, effects such as improved performance of semiconductor device according to example embodiments, reduced power consumption, and increased operational reliability may be achieved.

The air gap AG may be formed between adjacent metal wires to solve problems such as RC delay, mutual interference and increased power consumption that occur as the gap between adjacent metal wires in the interconnection layer 250 gradually decreases, and problem with rapidly increasing capacitance values such as parasitic capacitance as the spacing between adjacent metal wires decreases in particular.

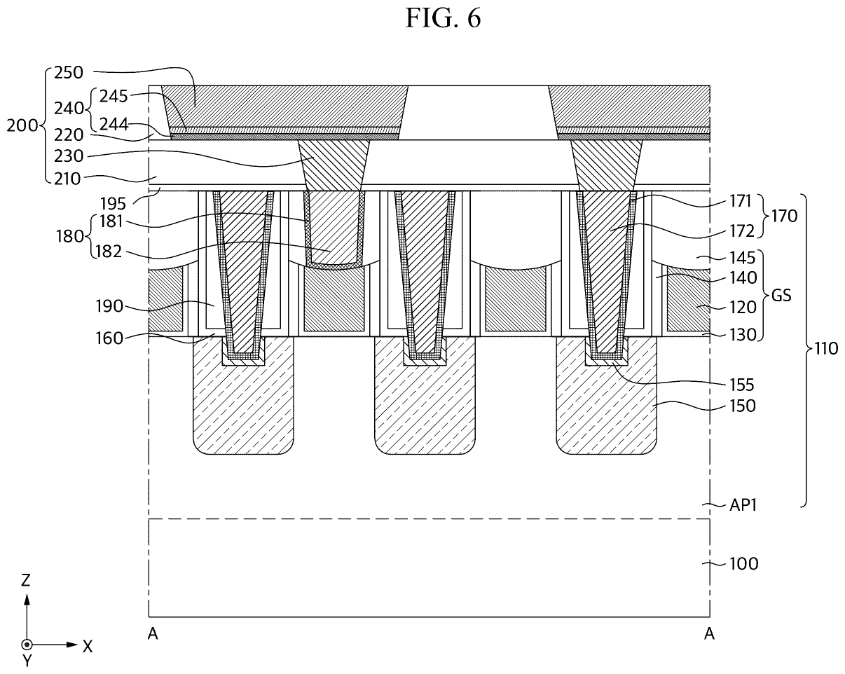

Referring to FIG. 6, the adhesion layer 240 may have a multi-layer structure. The adhesion layer 240 may include multiple layers. For example, the adhesion layer 240 may include a first layer 244 and a second layer 245. The second layer 245 may be placed on the first layer 244.

According to some example embodiments, a multi-layer structure of the adhesion layer 240 may have a structure in which TaB or its alloy and one or more material selected from the group consisting of Ru, Rh, Ir, Mo, Cu, Co, W, RuAl, NiAl, NbB₂, MoB₂ and MoW are alternately stacked. For the implementation of low resistance through interaction between adhesion layer and interconnection layer and for the control on deterioration or breakage of metal wiring, the adhesion layer 240, which has a multi-layer structure, may have a structure in which TaB and Ru are alternately stacked. For example, the first layer 244 may include TaB, and the second layer 245 may include Ru.

According to some example embodiments, when the adhesion layer 240 has a multilayer structure, each of the first layer 244 and the second layer 24% may have a thickness of 0.5 Å to 10 Å. The total thickness of the adhesion layer 240 including the first layer 244 and the second layer 245 may be controlled to 20% or less of the thickness of the interconnection layer 250. Not illustrated in FIG. 6, but when the adhesion layer 240 has a multilayer structure, the adhesion layer may further include a plurality of n-th adhesion layers (n is an integer from 3 to 40) in addition to the first layer 244 and the second layer 245.

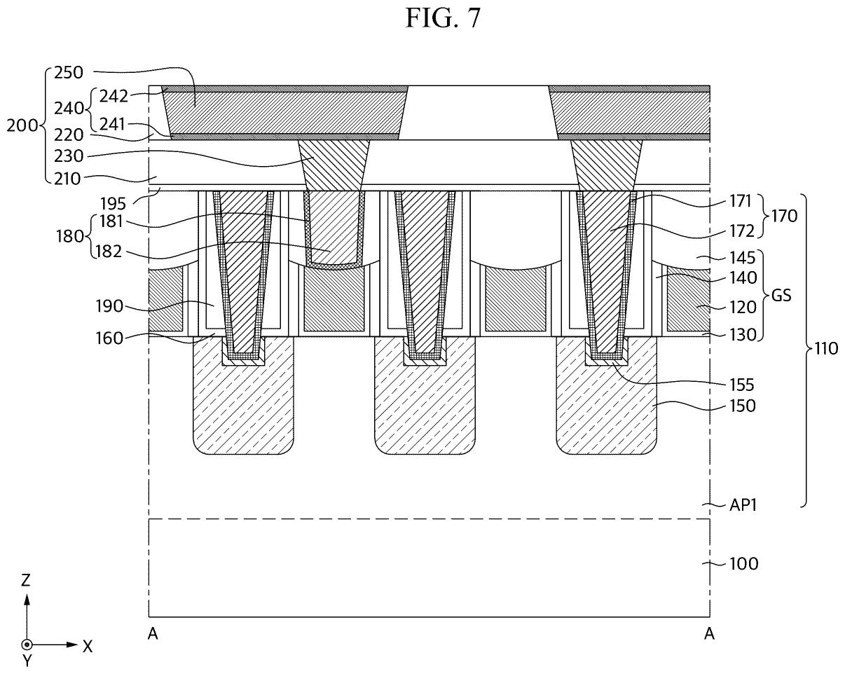

Referring to FIG. 7, the adhesion layer 240 may include multiple layers. For example, the adhesion layer 240 may include the first adhesion layer 241 and the second adhesion layer 242. The second adhesion layer 242 may be placed on the interconnection layer 250. The second adhesion layer 242 may cover the interconnection layer 250. The second adhesion layer 242 may extend along the upper surface of the interconnection layer 250. Each of the first adhesion layer 241 and the second adhesion layer 242 may include TaB or an alloy of TaB. For example, the first adhesion layer 241 and the second adhesion layer 242 may include the same material. For another example, the first adhesion layer 241 and the second adhesion layer 242 may include different materials.

According to some example embodiments, the interconnection layer 250 may be placed between the first adhesion layer 241 and the second adhesion layer 242. More specifically, the interconnection layer 250 may be disposed between the first adhesion layer 241 and the second adhesion layer 242 in the third direction Z.

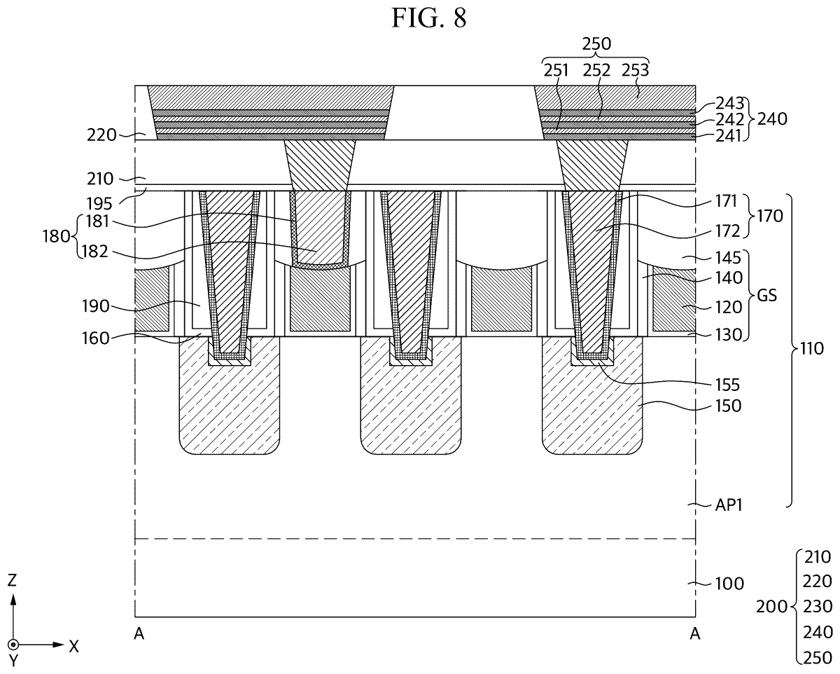

Referring to FIG. 8, the adhesion layer 240 may be arranged alternately with the interconnection layer 250. The adhesion layer 240 and the interconnection layer 250 may each have a multi-layer structure.

According to some example embodiments, the adhesion layer 240 may include the first adhesion layer 241 to a third adhesion layer 243. The interconnection layer 250 may include a first interconnection layer 251 to a third interconnection layer 253. The thickness of the third interconnection layer 253 may be greater than the thickness of each of the first interconnection layer 251 and a second interconnection layer 252. The first adhesion layer 241 to the third adhesion layer 243 and the first interconnection layer 251 to the third interconnection layer 253 may be arranged alternately. The first interconnection layer 251 may be placed on the first adhesion layer 241. The second adhesion layer 242 may be placed on the first interconnection layer 251. The second interconnection layer 252 may be placed on the second adhesion layer 242. The third adhesion layer 243 may be placed on the second interconnection layer 252. The third interconnection layer 253 may be placed on the third adhesion layer 243.

FIG. 8 illustrates that three adhesion layers which are the first adhesion layer 241 to the third adhesion layer 243 and three interconnection layers which are the first interconnection layer 251 to the third interconnection layer 253 are arranged alternately, but example embodiments are not limited thereto. The number of adhesion layers 240 and the interconnection layers 250 that are alternately stacked, may vary depending on the example embodiment. For example, two adhesion layers 240 and two interconnection layers 250 may be alternated. For another example embodiment, four or more adhesion layers 240 and four or more interconnection layers 250 may be alternated.

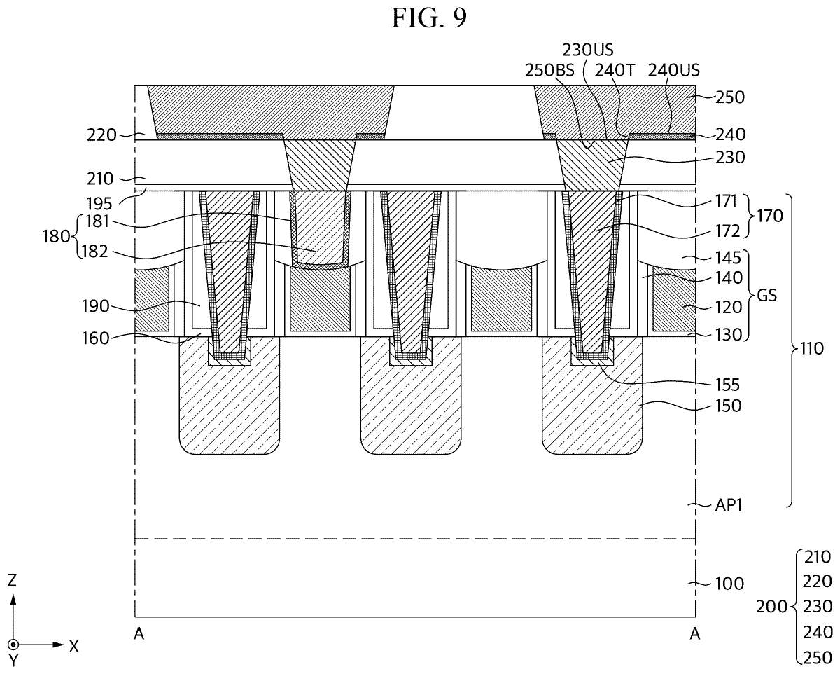

Referring to FIGS. 9 to 11, a portion of the interconnection layer 250 may contact the via 230 without intermediary through the adhesion layer 240. The upper surface of the via 230US may be in contact with a first portion of the interconnection layer 250. From the perspective of electrical signal transmission, it may be more advantageous for at least a portion of the interconnection layer 250 to contact the via 230 without intermediary through the adhesion layer 240.

Referring to FIG. 9, the adhesion layer 240 may not be placed on an upper surface of the via 230US. A trench 240T exposing the upper surface of the via 230US may be disposed within the adhesion layer 240. The interconnection layer 250 may fill the trench 240T within the adhesion layer 240. The interconnection layer 250 may overlap the adhesion layer 240 in the first direction X. The upper surface of the via 230US and a bottom surface of the interconnection layer 250BS may be in contact. Based on the substrate 100, the bottom surface of the interconnection layer 250BS, which is in contact with the upper surface of the via 230US, may be placed below an upper surface of the adhesion layer 240US.

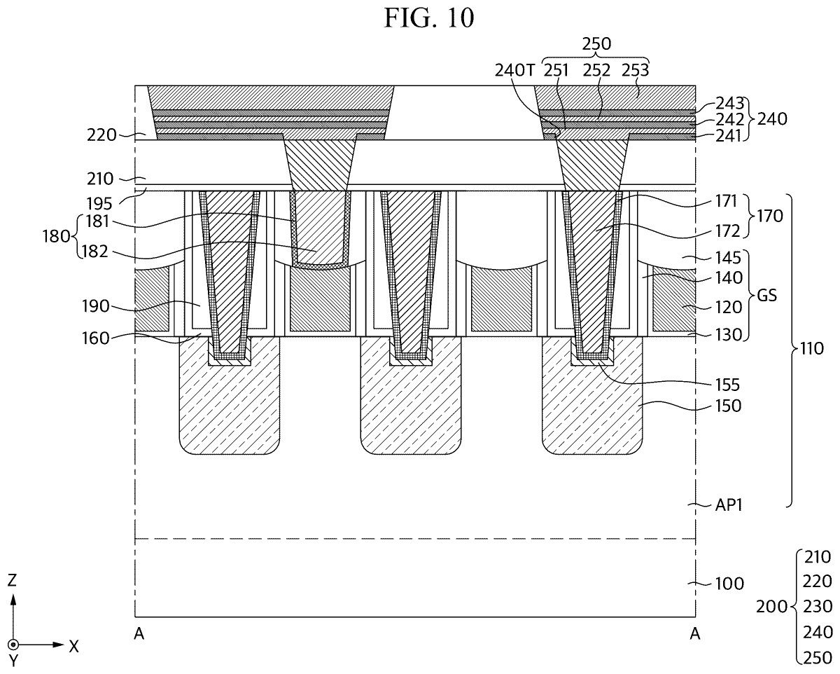

Referring to FIG. 10, one interconnection layer 251 of the plurality of interconnection layers 250 may fill the trench 240T within the adhesion layer 240. For example, the first interconnection layer 251 may fill the trench 240T within the first adhesion layer 241. The upper surface of the via 230 may contact the bottom surface of the first interconnection layer 251. The first interconnection layer 251 within the trench 240T within the first adhesion layer 241 may overlap the first adhesion layer 241 in the first direction X.

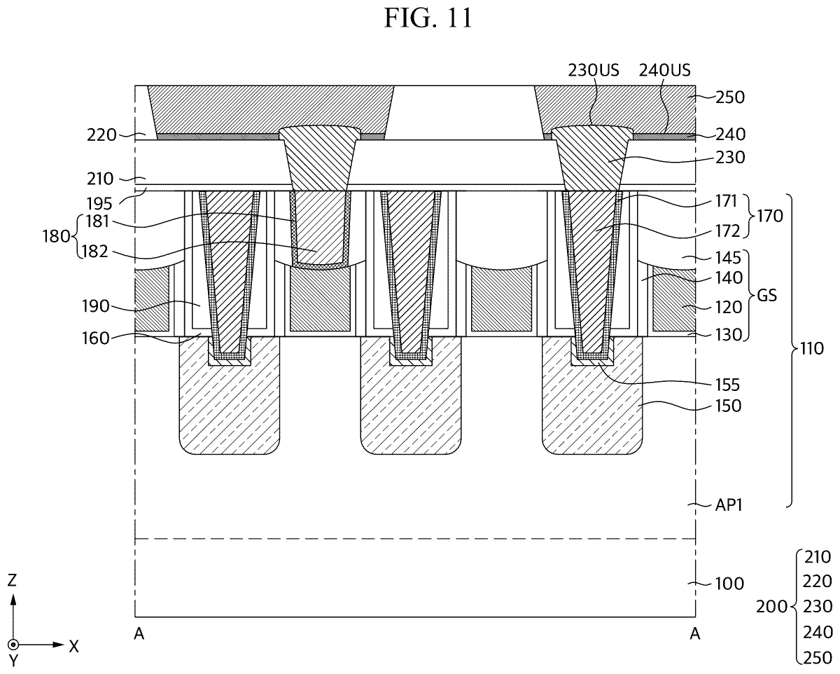

Referring to FIG. 11, the via 230 may penetrate the adhesion layer 240. The upper area of the via 230 may further exist at the vertical level where the adhesion layer 240 is located. The upper area of the via 230 may overlap the adhesion layer 240 in the first direction X. The upper surface of the via 230US may protrude convexly from the adhesion layer 240 toward the interconnection layer 250. The upper surface of the via 230US may protrude toward the interconnection layer 250 more than the upper surface of the adhesion layer 240US.

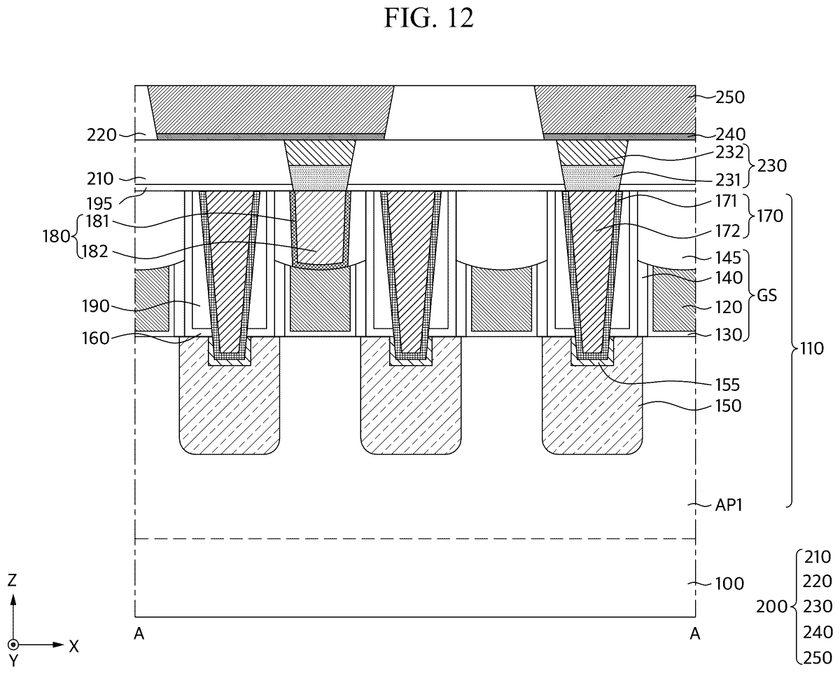

Referring to FIG. 12, the via 230 may include multiple layers. For example, the via 230 may include a first via layer 231 and a second via layer 232. The first via layer 231 and the second via layer 232 may include different materials. For example, the first via layer 231 may include Mo, and the second via layer 232 may include Ru, but they are not limited thereto.

According to some example embodiments, the second via layer 232 may include the same material as the interconnection layer 250. For example, the second via layer 232 and the interconnection layer 250 may each include one or more elements or compounds selected from the group consisting of Ru, Rh, Ir, Mo, Cu, Co, W, RuAl, NiAl, NbB₂, MoB₂, CuAl, CuAl₂ and MoW. FIG. 12 illustrates that the first via layer 231 and the second via layer 232 are stacked vertically, but the present disclosure is not limited thereto.

According to some example embodiments, in the third direction Z, both the thickness of the first via layer 231 and the thickness of the second via layer 232, may be greater than the thickness of the adhesion layer 240. Here, the thickness of the first via layer 231 may refer to the distance between the upper surface and the bottom surface of the first via layer 231 in the third direction Z. Likewise, the thickness of the second via layer 232 may refer to the distance between the upper surface and the bottom surface of the second via layer 232 in the third direction Z. According to some example embodiments in the third direction Z, the thickness of one or both of the first via layer 231 and the thickness of the second via layer 232, may be greater a combined thickness of the adhesion layer 240, when the adhesion layer includes multiple adhesion layers

According to some example embodiments, in the third direction Z, the thickness of the first via layer 231 and the thickness of the second via layer 232 may be the same. According to some example embodiments, in the third direction Z, the ratio of the thickness of the first via layer 231 and the thickness of the second via layer 232 may be 3:7 to 7:3.

FIG. 12 illustrates that on the multi-layer via 230, the adhesion layer 240 extends to cover the upper surface of the via 230, but the present disclosure is not limited thereto. For example, the via 230 may have a multi-layer structure including the first via layer 231 and the second via layer 232, and as illustrated in FIGS. 9 to 11, the adhesion layer 240 does not cover the upper surface of the via 230, and the interconnection layer 250 may contact the via 230 exposed between the adhesion layers 240. The via 230 having a multi-layer structure including the first via layer 231 and the second via layer 232 may be applied in combination with other example embodiments.

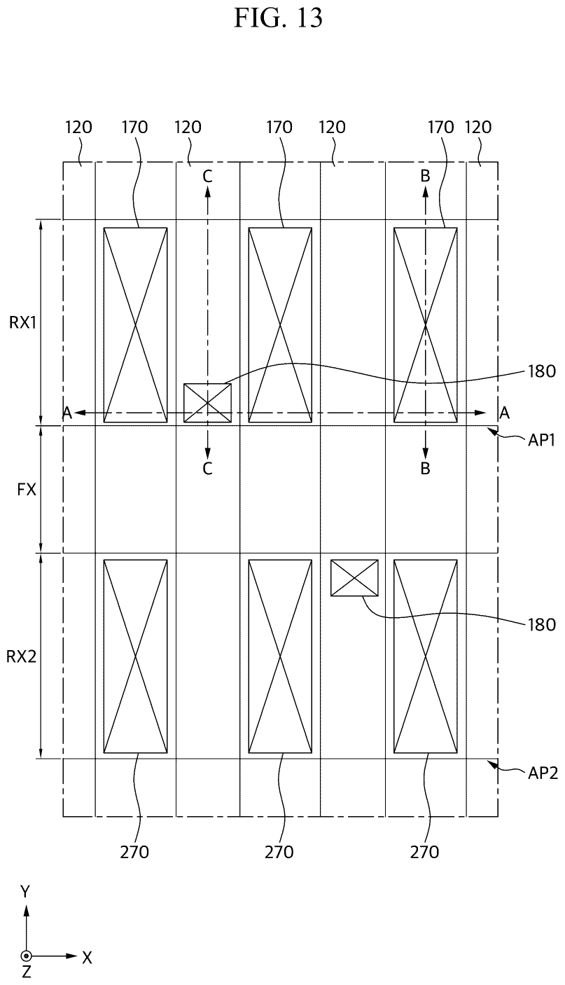

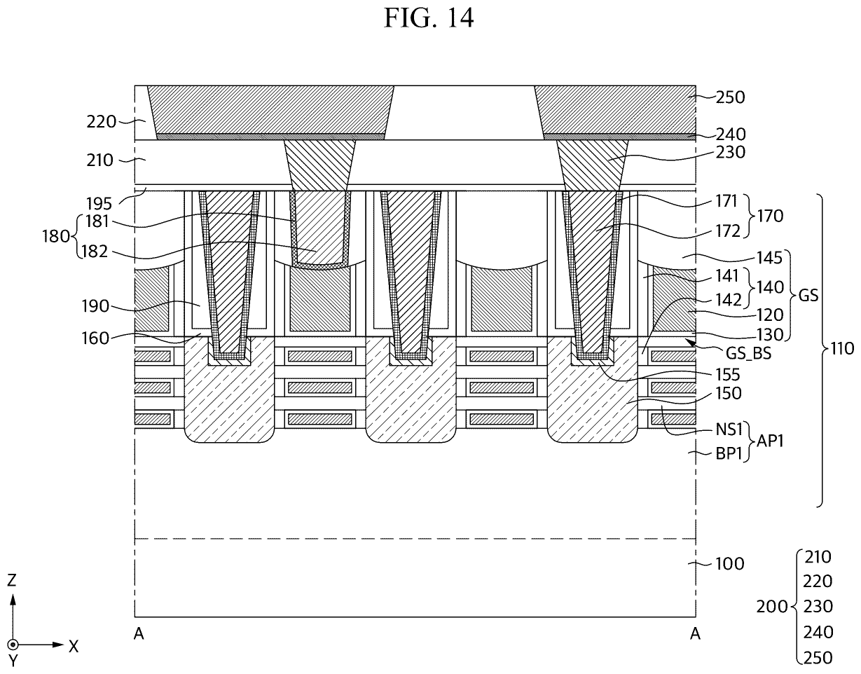

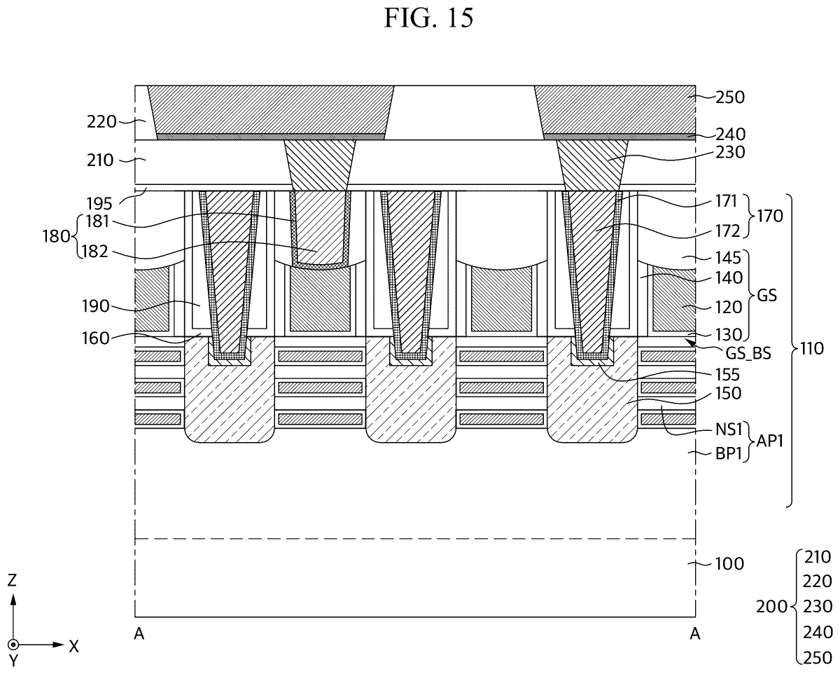

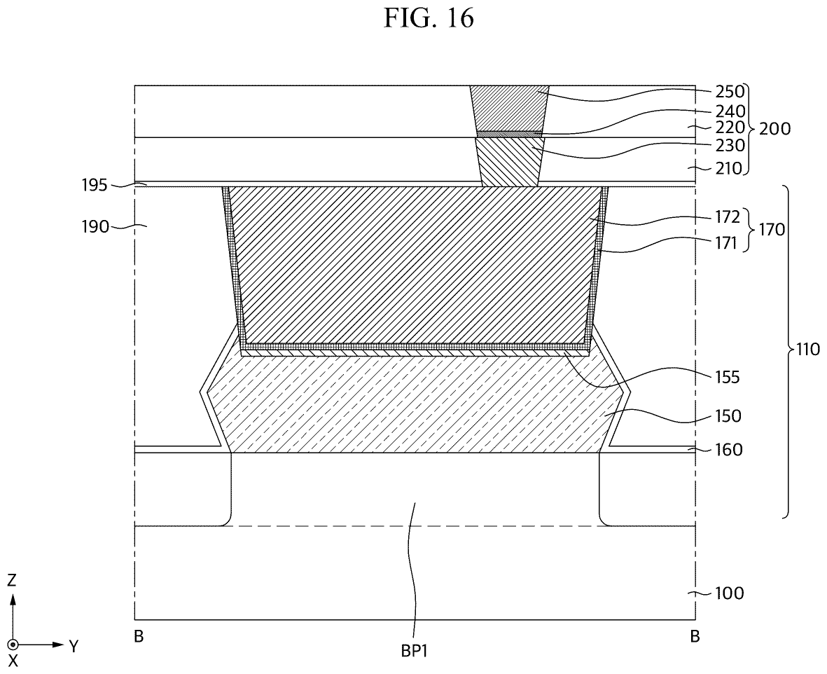

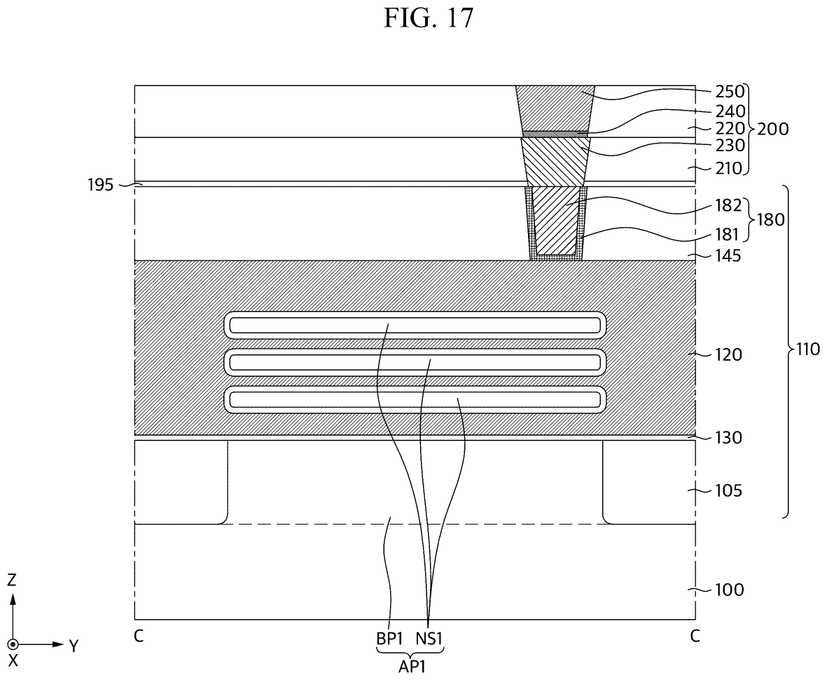

FIGS. 13 to 17 are diagrams of semiconductor devices according to other example embodiments. For reference, FIG. 13 is a layout diagram for explaining a semiconductor device according to an example embodiment. FIGS. 14 and 15 are cross-sectional views taken along line A-A of FIG. 13, respectively. FIG. 16 is a cross-sectional view taken along line B-B of FIG. 13. FIG. 17 is a cross-sectional view taken along line C-C of FIG. 13. For convenience of explanation, differences from those described with reference to FIGS. 1 to 4 will be mainly explained.

Referring to FIGS. 13 to 17, in the semiconductor device, the first activation pattern AP1 may include a bottom pattern BP1 and a sheet pattern NS1.

Not illustrated, but the second activation pattern AP2 may also include a bottom pattern and a sheet pattern.

According to some example embodiments, the bottom pattern BP1 may extend along the first direction X. The sheet pattern NS1 may be placed on the bottom pattern BP1 and spaced apart from the bottom pattern BP1.

According to some example embodiments, the sheet pattern NS1 may include a plurality of sheet patterns stacked in the third direction Z. It is illustrated in FIG. 17 that there are three sheet patterns NS1, but it is only for convenience of explanation, and the present disclosure is not limited thereto. The upper surface of the sheet pattern NS1 placed at the top of the sheet pattern NS1 may be the upper surface of the first activation pattern AP1.

According to some example embodiments, the sheet pattern NS1 may be connected to the source/drain pattern 150. The sheet pattern NS1 may be a channel pattern used as a channel region of a transistor. For example, the sheet pattern NS1 may be a nanosheet or nanowire.

According to some example embodiments, the bottom pattern BP1 may include silicon or germanium, which are elemental semiconductor materials. Alternatively, the bottom pattern BP1 may include a compound semiconductor. For example, a group IV-IV compound semiconductor or a group III-V compound semiconductor may be included.

According to some example embodiments, the sheet pattern NS1 may include silicon or germanium, which are elemental semiconductor materials. Alternatively, the sheet pattern NS1 may include a compound semiconductor, and for example, the sheet pattern NS1 may include a group IV-IV compound semiconductor, or a group III-V compound semiconductor.

According to some example embodiments, the gate insulation film 130 may extend along the upper surface of the bottom pattern BP1 and the upper surface of the field insulation film 105. The gate insulation film 130 may surround the perimeter of the sheet pattern NS1.

According to some example embodiments, the gate electrode 120 may be placed on the bottom pattern BP1. The gate electrode 120 may intersect the bottom pattern BP1. The gate electrode 120 may surround the perimeter of the sheet pattern NS1. The gate electrode 120 may be disposed between the bottom pattern BP1 and the sheet pattern NS1, and between the adjacent sheet patterns NS1.

In FIG. 14, the gate spacer 140 may include an outer spacer 141 and an inner spacer 142. The inner spacer 142 may be disposed between the bottom pattern BP1 and the sheet pattern NS1, and between the adjacent sheet patterns NS1.

In FIG. 15, the gate spacer 140 may include only an outer spacer 141 in FIG. 13. An inner spacer is not disposed between the bottom pattern BP1 and the sheet pattern NS1 and between the adjacent sheet patterns NS1.

According to some example embodiments, the bottom surface of the source/drain contact 170 may be located between the upper surface of the sheet pattern NS1 placed at the bottom among multiple sheet patterns NS1 and the bottom surface of the sheet pattern NS1 placed at the top. In example embodiments, the bottom surface of the source/drain contact 170 may be located between the upper surface of the sheet pattern NS1 placed at the top and the bottom surface of the sheet pattern NS1 placed at the top.

According to some example embodiments, the description of the metal interconnection structure 200 is omitted because it is substantially the same as the content described with reference to FIGS. 1 to 4.

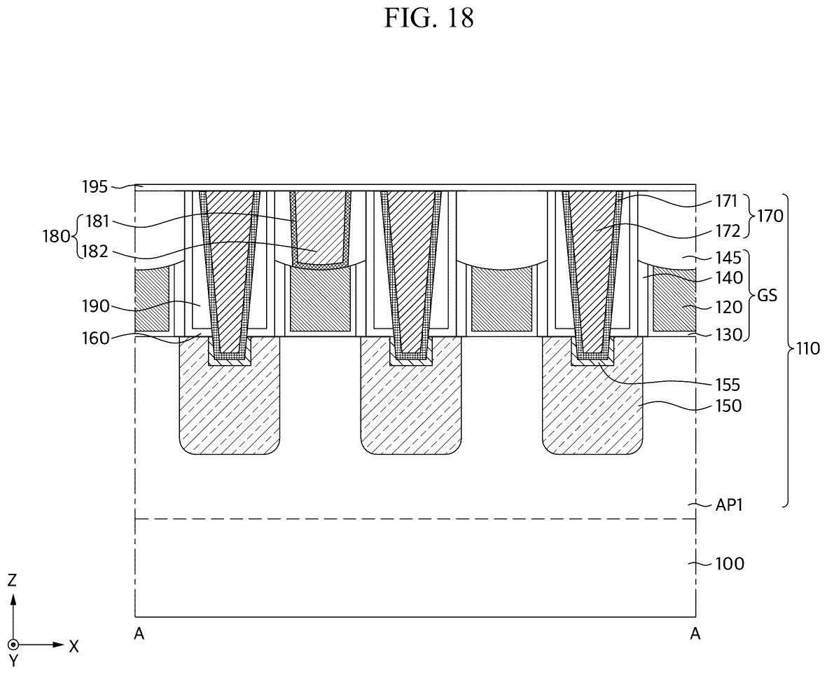

FIGS. 18 to 21 are diagrams illustrating intermediate operations of a method of manufacturing a metal interconnection structure according to example embodiments. For reference, FIGS. 18 to 21 illustrate intermediate operations of the manufacturing method of the metal interconnection structure illustrated in FIG. 2 or FIG. 5.

Referring to FIG. 18, the device layer 110 may be formed on the substrate 100.

Specifically, on the first activation pattern AP1, the source/drain pattern 150 may be formed. The source/drain etch stopping film 160 and the interlayer insulation film 190 are sequentially formed on the source/drain pattern 150 in that order. After forming the interlayer insulation film 190, the gate structure GS may be formed through a replacement metal gate (RMG) process.

Subsequently, the source/drain contact 170 that penetrates (or is positioned through) the interlayer insulation film 190, may be formed, and the gate contact 180 penetrating the gate capping layer 145 may be formed. The device layer etch stopping film 195 may be formed on the interlayer insulation film 190, the source/drain contact 170 and the gate contact 180.

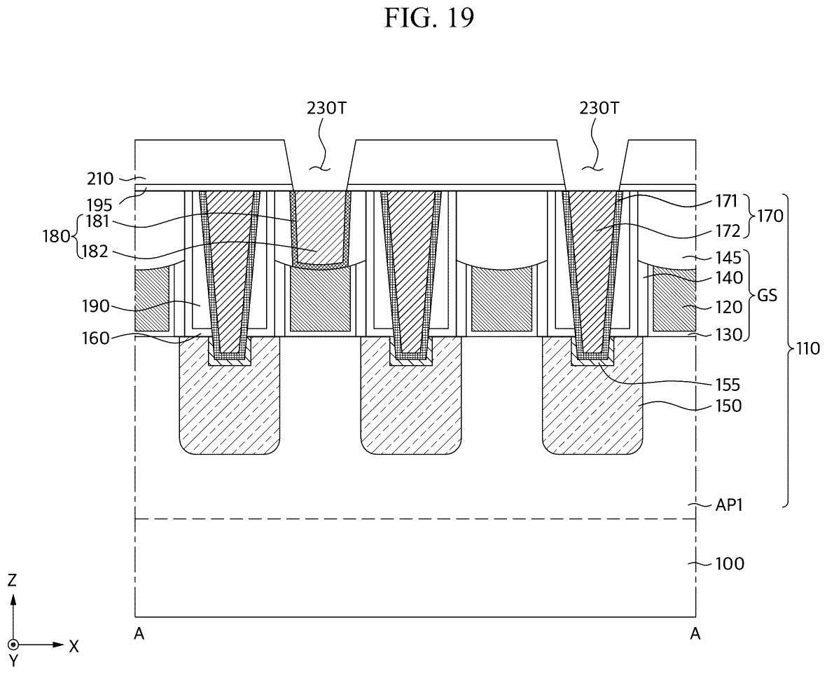

Referring to FIG. 19, the first insulation layer 210 may be formed on the device layer 110, and a via trench 230T may be formed within the first insulation layer 210.

According to some example embodiments, the first insulation layer 210 may cover the device layer 110. The first insulation layer 210 may be formed to extend on the device layer etch stopping film 195.

According to some example embodiments, the via trench 230T may be formed to penetrate the first insulation layer 210. The via trench 230T may be formed to penetrate the first insulation layer 210 and expose either the source/drain contact 170 or the gate contact 180.

More specifically, a mask film may be formed on the first insulation layer 210. A mask pattern may be formed on the mask film. For example, the mask film may include, but is not limited to, oxide. By using the mask pattern as a mask, the via trench 230T may be formed within the first insulation layer 210.

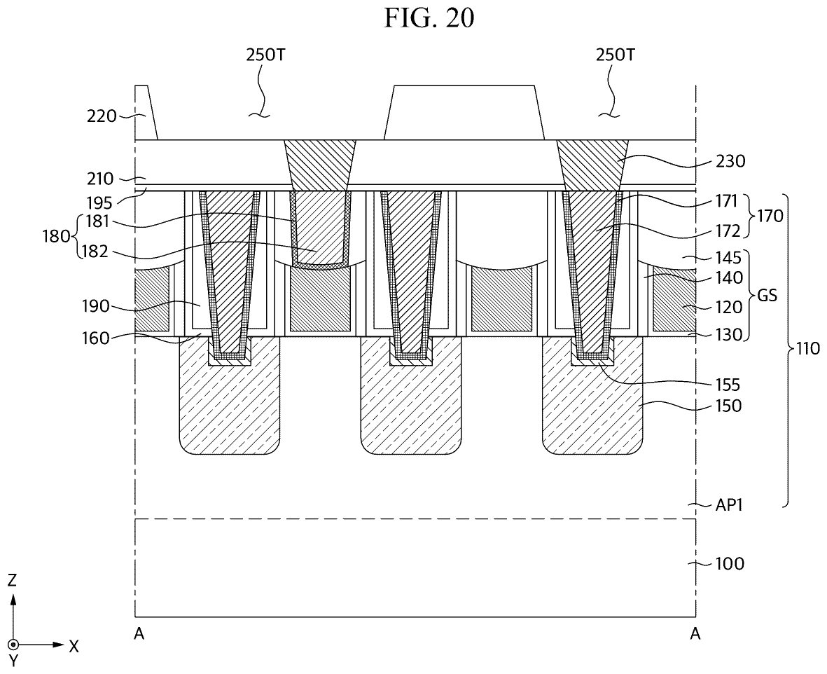

Referring to FIG. 20, the via 230 may be formed, and an interconnection trench 250T may be formed within the second insulation layer 220.

According to some example embodiments, the via 230 may fill the via trench 230T of FIG. 19. The second insulation layer 220 may be formed to cover the first insulation layer 210 and the via 230.

According to some example embodiments, the interconnection trench 250T may be formed to penetrate the second insulation layer 220. The interconnection trench 250T may penetrate the second insulation layer 220 and expose the upper surface of the via 230. The method of forming the interconnection trench 250T may be the same as the method of forming the via trench 230T in FIG. 19.

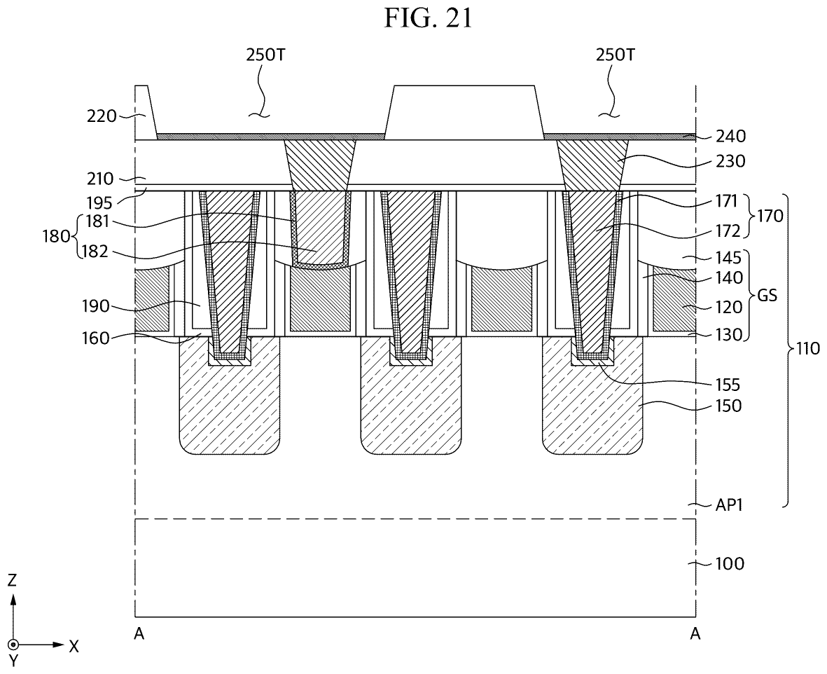

Referring to FIG. 21, the adhesion layer 240 may be formed within the interconnection trench 250T. The adhesion layer 240 may be formed within the interconnection trench 250T through physical vapor deposition (PVD), chemical vapor deposition (CVD), or atomic layer deposition (ALD).

The adhesion layer 240 may extend along the bottom surface of the interconnection trench 250T. The adhesion layer 240 may cover the upper surface of the via 230. The adhesion layer 240 may include TaB or an alloy of TaB.

Further, referring to FIG. 2, the interconnection layer 250 that fills the interconnection trench 250T may be formed. The interconnection layer 250 may be formed within the interconnection trench 250T through the PVD, the CVD, or the ALD.

By placing the adhesion layer 240 within the interconnection trench 250T, the interconnection layer 250 may be stably electrically connected to the via 230. The interconnection layer 250 may include one or more material selected from the group consisting of Ru, Rh, Ir, Mo, Cu, Co, W, RuAl, NiAl, NbB₂, MoB₂ and MoW.

The interconnection layer 250 may be formed to have a thickness of 100 Å to 300 Å. The distance from the upper surface of the adhesion layer 240 to the upper surface of the interconnection layer 250 may be 100 Å to 300 Å.

Further, referring to FIG. 5, the air gap AG may be formed between the interconnection layers 250. For example, the air gap AG may be formed through plasma treatment at a temperature of 400° C. or higher.

According to some example embodiments, the adhesion layer 240 including TaB may prevent the interconnection layer 250 and the via 230 from being disconnected during the process of forming the air gap AG. For example, in forming the air gap AG, the thickness of the interconnection layer 250 may be reduced, a deterioration phenomenon in which the upper area of the interconnection layer 250 is rounded may occur or the interconnection layer 250 may be disconnected. However, according to example embodiments of the present disclosure, it may be sufficiently controlled even after going through the air gap formation described above.

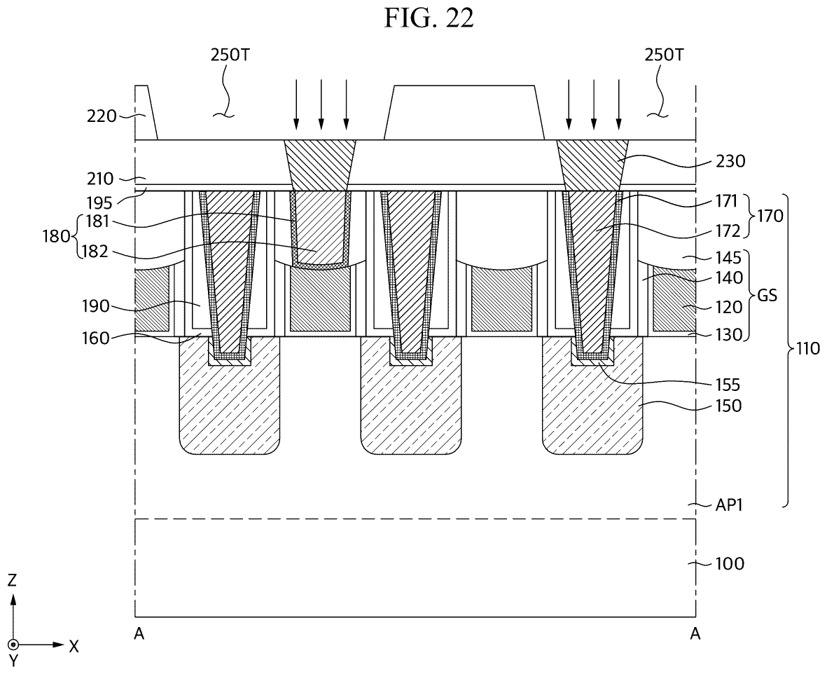

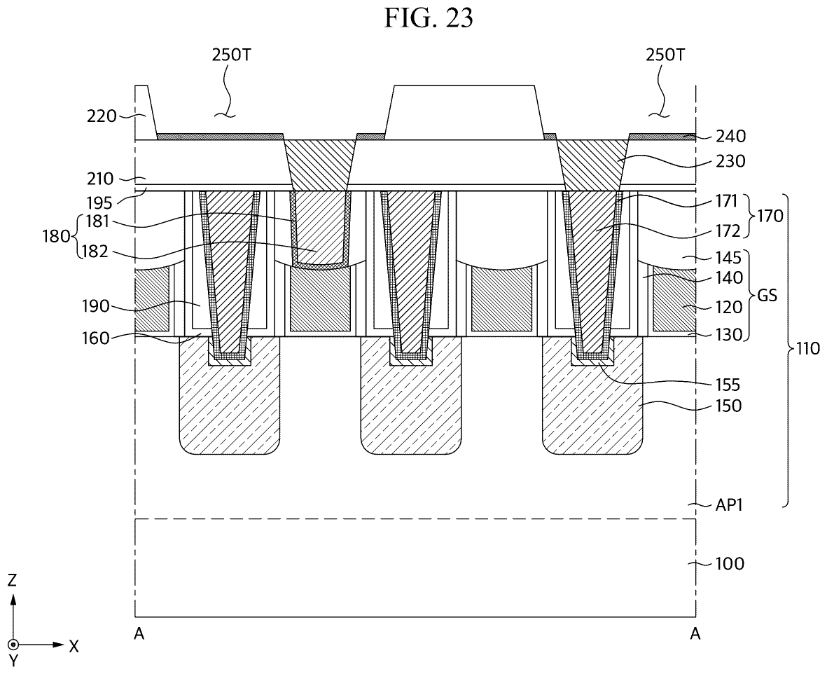

FIGS. 22 and 23 are diagrams illustrating intermediate operations of a method of manufacturing a metal interconnection structure according to other example embodiments. For reference, FIGS. 22 and 23 are diagrams illustrating intermediate operations of a method of manufacturing the metal interconnection structure illustrated in FIG. 9. Further, for reference, FIG. 22 is a diagram illustrating operations after FIG. 20. For convenience of explanation, differences from those described with reference to FIGS. 18 to 21 will be mainly explained.

Referring to FIGS. 20 to 22, an inhibitor may be treated on the via 230. For example, the inhibitor may be applied on the upper surface of the via 230. The inhibitor may chemically react with substances contained in the via 230. Examples of inhibitors include self-assembled monolayers (SAMs), but are not limited thereto.

Referring to FIG. 23, the adhesion layer 240 may be formed.

According to some example embodiments, the adhesion layer 240 may not be formed on the via 230 on which the inhibitor is applied. Therefore, even if the adhesion layer 240 is formed within the interconnection trench 250T, the adhesion layer 240 may not be formed on the upper surface of the via 230. Therefore, the upper surface of the via 230 may remain exposed within the interconnection trench 250T.

Further, referring to FIG. 9, the interconnection layer 250 that fills the interconnection trench 250T may be formed. The upper surface of the via 230 on which the adhesion layer 240 is not formed by the inhibitor may contact the interconnection layer 250.

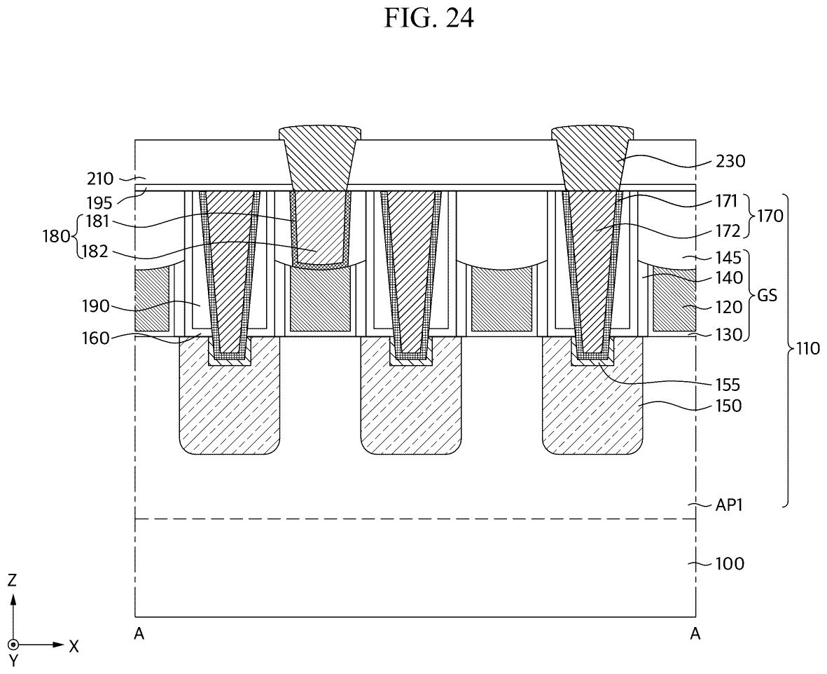

FIGS. 24 to 26 are diagrams illustrating intermediate operations of a method of manufacturing a metal interconnection structure according to other example embodiments. For reference, FIGS. 24 to 26 are diagrams illustrating intermediate operations of a method of manufacturing the metal interconnection structure illustrated in FIG. 11. Further, for reference, FIG. 24 is a diagram illustrating operations after FIG. 19. For convenience of explanation, differences from those described with reference to FIGS. 22 and 23 will be mainly explained.

Referring to FIGS. 19 and 24, the via 230 filling the via trench 230T may be formed. The via 230 may be formed to protrude above the upper surface of the first insulation layer 210. Based on the upper surface of the substrate 100, the upper surface of the via 230 may be formed above the upper surface of the first insulation layer 210.

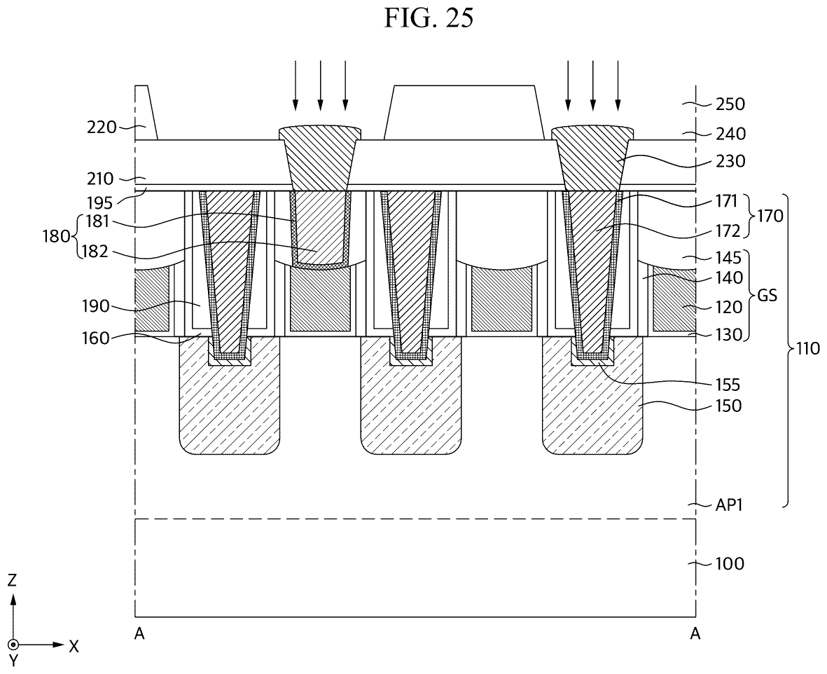

Referring to FIG. 25, the inhibitor may be processed on the via 230. For example, the inhibitor may be applied on the upper surface of the via 230. The inhibitor may chemically react with substances contained in the via 230.

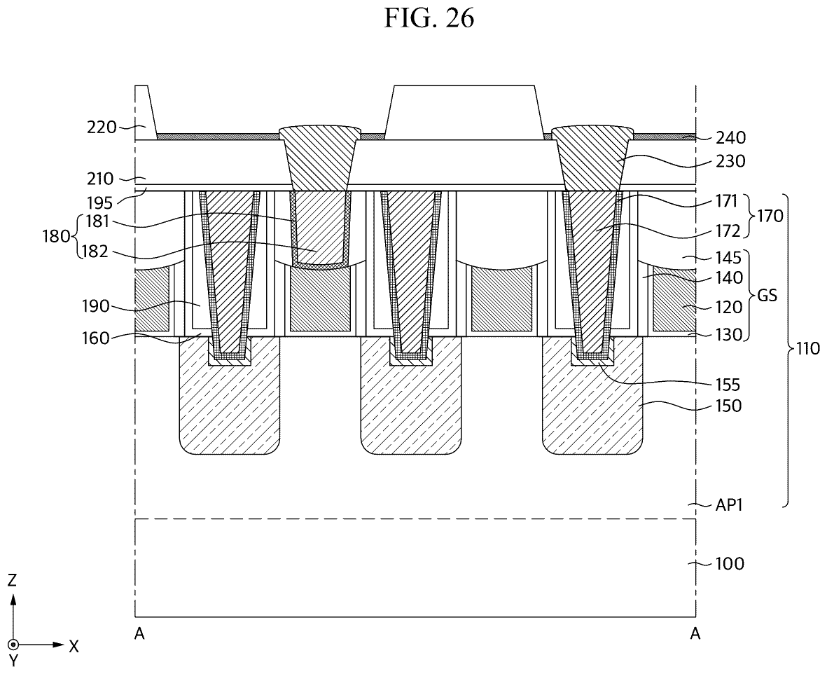

Referring to FIG. 26, the adhesion layer 240 may be formed. The adhesion layer 240 may not be formed on the via 230 on which the inhibitor is applied. Therefore, even if the adhesion layer 240 is formed within the interconnection trench 250T, the adhesion layer 240 may not be formed on the upper surface of the via 230. Therefore, the upper surface of the via 230 may remain exposed without being covered by the adhesion layer 240 within the interconnection trench 250T. Based on the upper surface of the substrate 100, the upper surface of the via 230 may be placed above the upper surface of the adhesion layer 240.

Further, referring to FIG. 11, the interconnection layer 250 that fills the interconnection trench 250T may be formed. The upper surface of the via 230 on which the adhesion layer 240 is not formed by the inhibitor may contact the interconnection layer 250. Further, the via 230 formed to protrude more than the upper surface of the first insulation layer 210 may protrude above the adhesion layer 240 and contact the interconnection layer 250.

The example embodiments of the present disclosure are described with reference to the attached drawings. However, the present disclosure is not limited to the example embodiments, and the present disclosure can be manufactured in various other forms, and a person skilled in the art to which the present disclosure pertains will understand that the present disclosure can be implemented in other specific forms without changing its technical idea or essential features. Therefore, the example embodiments described above should be understood in all respects as illustrative and not limiting.

What is claimed is:

1. A semiconductor device comprising:
an activation pattern extended in a first direction;
a gate electrode having portions of the gate electrode spaced apart in the first direction on the activation pattern, and extending in a second direction intersecting the first direction;
a gate contact on the gate electrode;
a source/drain pattern on the activation pattern;
a source/drain contact on the source/drain pattern;
an insulation layer over the gate contact and the source/drain contact;
a via that penetrates the insulation layer, wherein the via is on at least one of the gate contact or the source/drain contact;
an adhesion layer on the insulation layer, wherein the adhesion layer exposes an upper surface of the via; and
an interconnection layer on the adhesion layer,
wherein the upper surface of the via is in contact with a first portion of the interconnection layer, and
wherein the adhesion layer includes tantalum boride (TaB) or an alloy of TaB.

2. The semiconductor device of claim 1, wherein a molar ratio of boron (B) of the adhesion layer to tantalum (Ta) of the adhesion layer, (N_{B}/N_{Ta}), is 5/95 to 30/70.

3. The semiconductor device of claim 1, wherein the alloy of TaB is an alloy of TaB and at least one element selected from the group consisting of Ru, Mo, Cu, Al and Pt.

4. The semiconductor device of claim 1, wherein the adhesion layer is a single layer structure or a multi-layer structure,
wherein the multi-layer structure comprises a first layer and a second layer that are stacked alternately,
wherein the first layer includes TaB or an alloy of TaB, and
wherein the adhesion layer includes one or more material selected from the group consisting of Ru, Rh, Ir, Mo, Cu, Co, W, RuAl, NiAl, NbB₂, MoB₂ and MoW.

5. The semiconductor device of claim 1, wherein the adhesion layer has a thickness that 20% or less of a thickness of the interconnection layer.

6. The semiconductor device of claim 1, wherein the via comprises a first via layer and a second via layer that are stacked.

7. The semiconductor device of claim 6, wherein both a thickness of the first via layer and a thickness of the second via layer, are greater than a thickness of the adhesion layer.

8. The semiconductor device of claim 1, wherein the via includes one or more material selected from the group consisting of W, Ti, TiN, Mo, Ru, Rh, Ir, Cu, Co, RuAl, NiAl, NbB₂, MoB₂ and MoW.

9. The semiconductor device of claim 1, wherein the activation pattern comprises a bottom pattern, and a sheet pattern that is placed over the bottom pattern,
wherein the sheet pattern is spaced apart from the bottom pattern, and
wherein the gate electrode surrounds the sheet pattern.

10. The semiconductor device of claim 1, wherein the via penetrates the adhesion layer.

11. The semiconductor device of claim 10, wherein the upper surface of the via protrudes convexly from the adhesion layer toward the interconnection layer.

12. The semiconductor device of claim 1, wherein the first portion of the interconnection layer that is in contact with the upper surface of the via, has a bottom surface that is below an upper surface of the adhesion layer.

13. The semiconductor device of claim 12, wherein the bottom surface of the first portion of the interconnection layer is coplanar with a bottom surface of the adhesion layer.

14. The semiconductor device of claim 1, wherein the interconnection layer comprises two or more interconnection layers spaced apart from each other in the first direction or in the second direction, with one or more air gaps between the two or more interconnection layers.

15. The semiconductor device of claim 1, further comprising an etch stopping film extending along a bottom surface of the insulation layer.

16. The semiconductor device of claim 1, the adhesion layer further comprises a second adhesion layer on the interconnection layer.

17. A method of manufacturing a metal interconnection structure, the method comprising:
forming an adhesion layer on an insulation layer; and
forming an interconnection layer on the adhesion layer,
wherein the adhesion layer includes tantalum boride (TaB) or an alloy of TaB, and
wherein the interconnection layer includes one or more material selected from the group consisting of Ru, Rh, Ir, Mo, Cu, Co, W, RuAl, NiAl, NbB₂, MoB₂, CuAl, CuAl₂ and MoW.

18. The method of claim 17, wherein forming the interconnection layer on the adhesion layer comprises arranging a plurality of interconnection layers spaced apart in a first direction or in a second direction, and
forming an air gap between the interconnection layers.

19. The method of claim 18, wherein forming the air gap comprises plasma treatment at a temperature of 400° C. or higher.

20. A semiconductor device comprising:
an activation pattern extended in a first direction;
a gate electrode having portions of the gate electrode spaced apart in the first direction on the activation pattern, and extending in a second direction intersecting the first direction;
a gate contact on the gate electrode;
a source/drain pattern on the activation pattern;
a source/drain contact on the source/drain pattern;
an insulation layer over the gate contact and the source/drain contact;
a via that penetrates the insulation layer and is on at least one of the gate contact or the source/drain contact;
an adhesion layer on the insulation layer, wherein the adhesion layer covers an upper surface of the via; and
an interconnection layer on the adhesion layer,
wherein the adhesion layer includes tantalum boride (TaB) or an alloy of TaB.
